(19) United States
(12) Patent Application Publication
(10) Pub. No.: US 2025/0011159 A1
(43) Pub. Date: Jan. 9, 2025

(54) ACCELERATION SENSOR

(71) Applicant: ROHM CO., LTD., Kyoto (JP)

(72) Inventors: Martin Wilfried HELLER, Kyoto-shi (JP); Toma FUJITA, Kyoto-shi (JP)

(73) Assignee: ROHM CO., LTD., Kyoto (JP)

(21) Appl. No.: 18/898,410

(22) Filed: Sep. 26, 2024

Related U.S. Application Data
(63) Continuation of application No. PCT/JP2022/048219, filed on Dec. 27, 2022.

(30) Foreign Application Priority Data
Mar. 30, 2022 (JP) 2022-057265
Mar. 30, 2022 (JP) 2022-057272

(51) Int. Cl. B81B 3/00; G01P 15/125

(52) U.S. Cl. CPC B81B 3/0086; G01P 15/125; B81B 2201/0235; B81B 2203/0163; B81B 2203/0307; B81B 2203/04; B81B 2207/07

(57) ABSTRACT

An acceleration sensor includes a device-side substrate having a first main surface and a second main surface facing the first main surface, a recessed portion recessed from the first main surface toward the second main surface side, a MEMS electrode that is provided in the recessed portion, includes a fixed electrode having a first fixed electrode and a second fixed electrode electrically insulated from the first fixed electrode, and a movable electrode having a first movable electrode and a second movable electrode electrically insulated from the first movable electrode, and constitutes a differential circuit, and an isolation joint that mechanically connects the first movable electrode and the second movable electrode while electrically insulating the first movable electrode and the second movable electrode.

### TECHNICAL FIELD

The present invention relates to an acceleration sensor.

### BACKGROUND ART

JP 2019-49434 A discloses a capacitive MEMS acceleration sensor (hereinafter, referred to as an acceleration sensor). The acceleration sensor includes a capacitor including a fixed electrode and a movable electrode, and detects a change in capacitance of a capacitor caused by displacement of the movable electrode when acceleration acts. The acceleration is calculated based on a detected change in capacitance of the capacitor.

As an acceleration sensor, a fully differential acceleration sensor is known. The fully differential acceleration sensor includes two proof masses, a first movable electrode and a second movable electrode connected to the two proof masses respectively, and a first fixed electrode and a second fixed electrode. First to fourth capacitors are constituted by a combination of the first and second movable electrodes and the first and second fixed electrodes.

According to a differential acceleration sensor, two symmetrical output voltages are detected when acceleration acts. These two output voltages may include common mode noise and an offset (hereinafter, collectively referred to as common mode noise and the like). However, by obtaining a difference between the two output voltages, output in which the common mode noise and the like are canceled can be obtained, and acceleration can be accurately calculated based on the output.

### BRIEF DESCRIPTION OF DRAWINGS

FIG. 1 is a plan view of an acceleration sensor according to a first embodiment of the present disclosure;

FIG. 2 is a plan view of a main part illustrating a MEMS electrode of the acceleration sensor in FIG. 1;

FIG. 3 is an enlarged plan view illustrating a periphery of a first region in FIG. 2;

FIG. 4 is a cross-sectional view taken along line IV-IV in FIG. 3;

FIG. 5 is a cross-sectional view taken along line V-V in FIG. 3;

FIG. 6 is a cross-sectional view taken along line VI-VI in FIG. 3;

FIG. 7 is a cross-sectional view taken along line VII-VII in FIG. 3;

FIG. 8A is a simplified element diagram illustrating the acceleration sensor of FIG. 1 in a simplified manner;

FIG. 8B is an equivalent circuit diagram of FIG. 8A;

FIG. 8C is an equivalent circuit diagram in which FIG. 8B is simplified;

FIG. 9 is a plan view illustrating the MEMS electrode of the acceleration sensor according to a second embodiment of the present disclosure;

FIG. 10 is an enlarged plan view illustrating an X1 side of FIG. 9;

FIG. 11 is a cross-sectional view taken along line XI-XI in FIG. 10;

FIG. 12 is a cross-sectional view taken along line XII-XII in FIG. 10;

FIG. 13 is a cross-sectional view taken along line XIII-XIII in FIG. 10;

FIG. 14 is an enlarged plan view illustrating an X2 side of FIG. 9;

FIG. 15 is a cross-sectional view taken along line XV-XV in FIG. 14;

FIG. 16 is a plan view illustrating the MEMS electrode of the acceleration sensor according to a third embodiment of the present disclosure;

FIG. 17 is an enlarged plan view illustrating a periphery of a first region in FIG. 16;

FIG. 18 is a cross-sectional view taken along line XVIII-XVIII in FIG. 17;

FIG. 19 is a cross-sectional view taken along line XIX-XIX in FIG. 17;

FIG. 20 is a cross-sectional view taken along line XX-XX of FIG. 17;

FIG. 21 is a plan view illustrating the MEMS electrode of the acceleration sensor according to a fourth embodiment of the present disclosure; and

FIG. 22 is a plan view illustrating the MEMS electrode of the acceleration sensor according to a fifth embodiment of the present disclosure.

### DETAILED DESCRIPTION

Hereinafter, an acceleration sensor according to an embodiment of the present disclosure will be described with reference to the accompanying drawings. Note that description below is merely exemplary in nature and is not intended to limit the present invention, its application, or its use.

### First Embodiment

(Overall configuration)

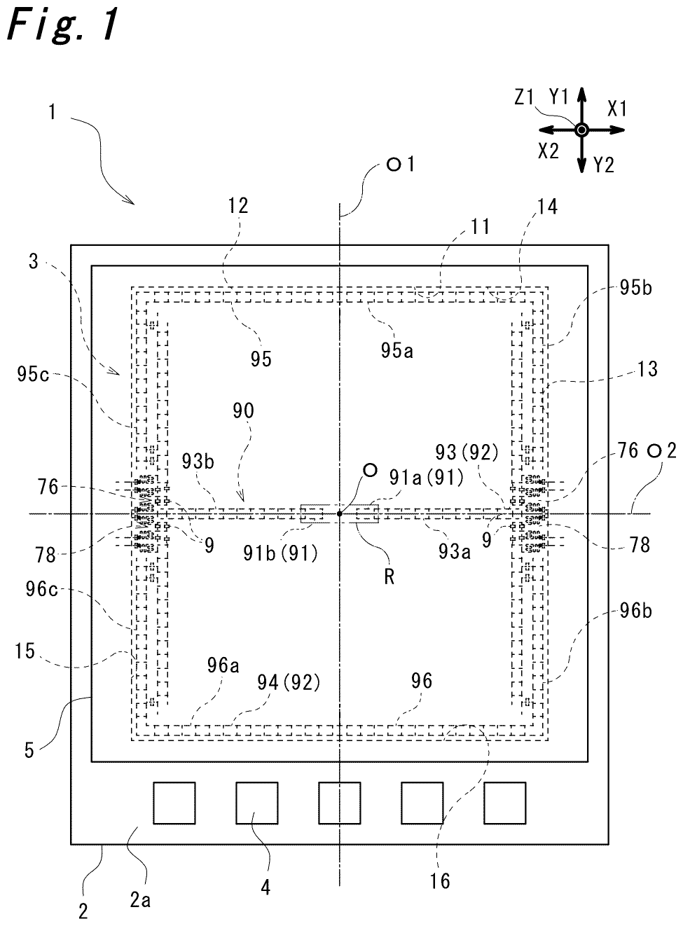

FIG. 1 is a schematic plan view illustrating an acceleration sensor 1 according to a first embodiment of the present disclosure. The acceleration sensor 1 is a uniaxial acceleration sensor that detects acceleration in a uniaxial direction. As illustrated in FIG. 1, the acceleration sensor 1 includes a device-side substrate 2 having a rectangular shape in plan view, a sensor unit 3 arranged at a central portion of the device-side substrate 2, an electrode pad 4 arranged on a side of the sensor unit 3 in the device-side substrate 2, and a lid-side substrate 5. Note that although size of the acceleration sensor 1 according to the present disclosure is not limited, the acceleration sensor 1 is formed to be relatively small using what is called a micro electro machining system (MEMS) technique.

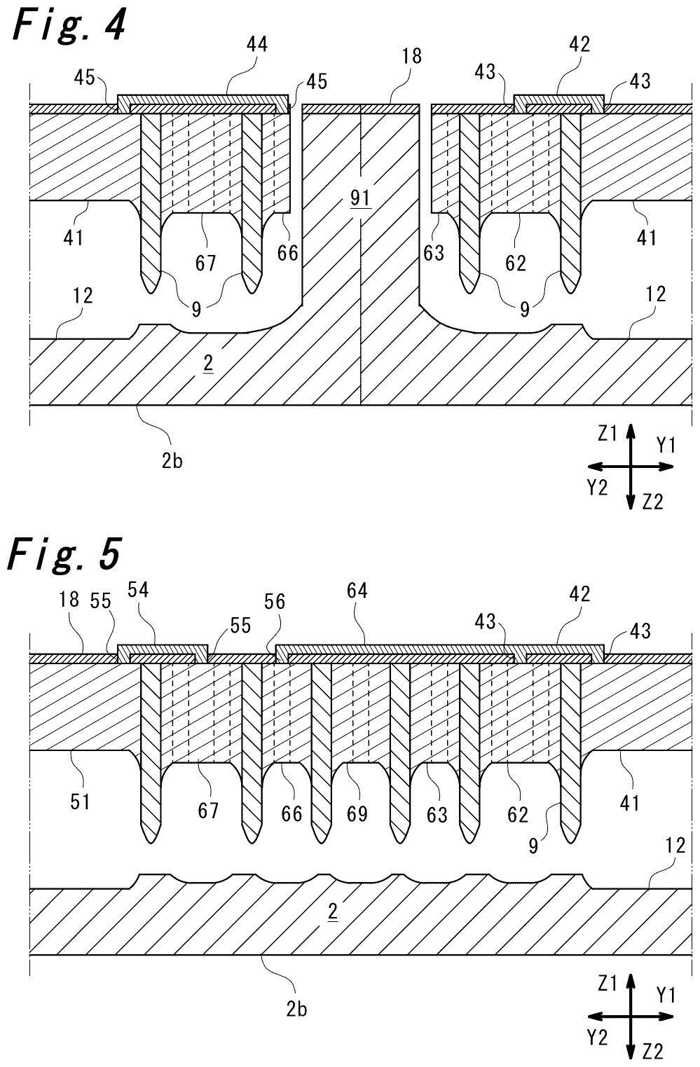

The device-side substrate 2 is made from conductive silicon, and includes a first main surface 2a to which the lid-side substrate 5 is bonded, and a second main surface 2b (see FIG. 4) located on a side opposite to the first main surface 2a and facing the first main surface 2a. Hereinafter, in FIG. 1, description will be made assuming that a left-right direction is an X direction, a vertical direction is a Y direction, and a direction orthogonal to the X direction and the Y direction is a Z direction. More specifically, in the X direction, the right side in FIG. 1 is referred to as an X1 side, the left side is referred to as an X2 side, and in the Y direction, the upper side in FIG. 1 is referred to as a Y1 side, and the lower side is referred to as a Y2 side. Further, as illustrated in FIGS. 4 to 7, in the Z direction, the first main surface 2a side is referred to as a Z1 side, and the second main surface 2b side is referred to as a Z2 side.

### (Configuration of Sensor Unit)

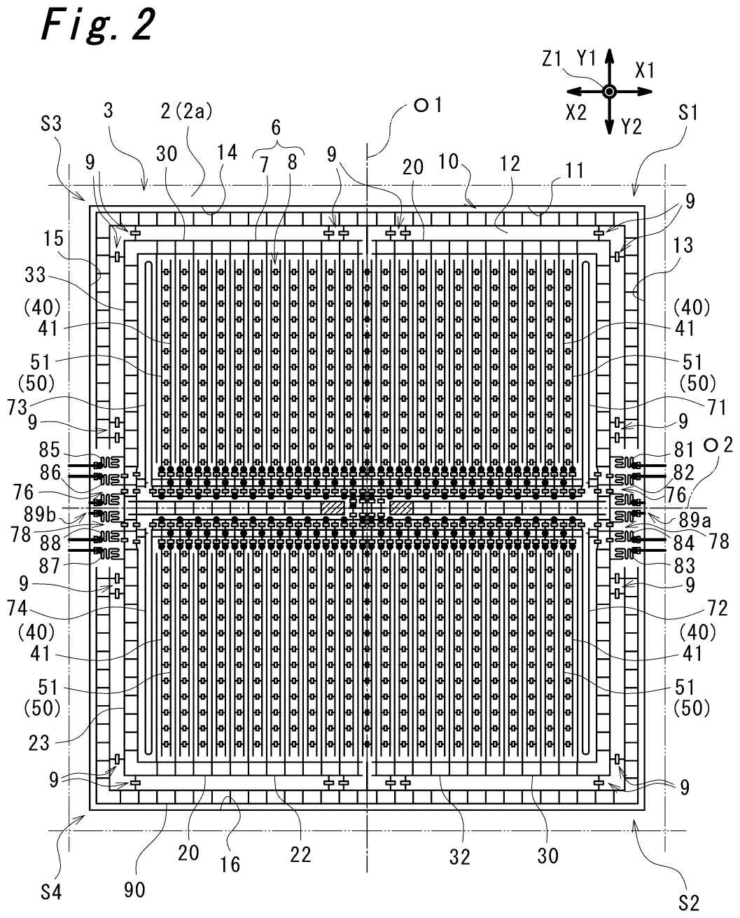

FIG. 2 is an enlarged plan view illustrating a periphery of the sensor unit 3 with the lid-side substrate 5 in FIG. 1 is removed. As illustrated in FIG. 2, the sensor unit 3 includes a recessed portion 10 formed in the device-side substrate 2, a MEMS electrode 6 located in the recessed portion, and a frame 90 that supports the MEMS electrode 6. The MEMS electrode 6 and the frame 90 are formed by processing the device-side substrate 2 made from conductive silicon by using a MEMS technique.

The recessed portion 10 is formed so as to be recessed from the first main surface 2a toward the second main surface 2b. The recessed portion 10 has a rectangular shape in plan view, and is defined by a plurality of recessed portion wall surfaces 11. A plurality of the recessed portion wall surfaces 11 include a recessed portion bottom surface 12 located on the Z2 side, and, in the recessed portion bottom surface 12, a recessed portion first side surface 13 extending from an X1-side edge portion toward the Z1 side, a recessed portion second side surface 14 extending from a Y1-side edge portion toward the Z1 side, a recessed portion third side surface 15 extending from an X2-side edge portion toward the Z1 side, and a recessed portion fourth side surface 16 extending from a Y2-side edge portion toward the Z1 side.

The recessed portion 10 is divided into a first region S1, a second region S2, a third region S3, and a fourth region S4 by an X-direction center line O1 passing through the center in the X direction and extending in the Y direction and a Y-direction center line O2 passing through the center in the Y direction and extending in the X direction in plan view. An intersection of the X-direction center line O1 and the Y-direction center line O2 is defined as a center O (see FIG. 1) of the recessed portion 10 (the recessed portion bottom surface 12).

Specifically, the first region S1 is located on the X1 side with respect to the X-direction center line O1 and on the Y1 side with respect to the Y-direction center line O2. The second region S2 is located on the X1 side with respect to the X-direction center line O1 and on the Y2 side with respect to the Y-direction center line O2. The third region S3 is located on the X2 side with respect to the X-direction center line O1 and on the Y1 side with respect to the Y-direction center line O2. The fourth region S4 is located on the X2 side with respect to the X-direction center line O1 and on the Y2 side with respect to the Y-direction center line O2.

### (Configuration of MEMS Electrode)

The MEMS electrode 6 includes a fixed electrode 7 and a movable electrode 8 having a comb shape. The fixed electrode 7 includes a first fixed electrode 20 and a second fixed electrode 30 electrically insulated from the first fixed electrode 20. The movable electrode 8 includes a first movable electrode 40 and a second movable electrode 50 electrically insulated from the first movable electrode 40. An insulating film 18 (see each cross-sectional view of FIGS. 4 to 7) made from an oxide film (for example, silicon oxide) is laminated on a surface on the Z1 side of the fixed electrode 7 and the movable electrode 8.

The first fixed electrode 20 is located in the first region S1 and the fourth region S4. The second fixed electrode 30 is located in the second region S2 and the third region S3. That is, each of the first fixed electrodes 20 and the second fixed electrodes 30 are arranged in regions located diagonally across the center O. On the other hand, the first and second movable electrodes 40 and 50 are located in each of the first to fourth regions S1 to S4.

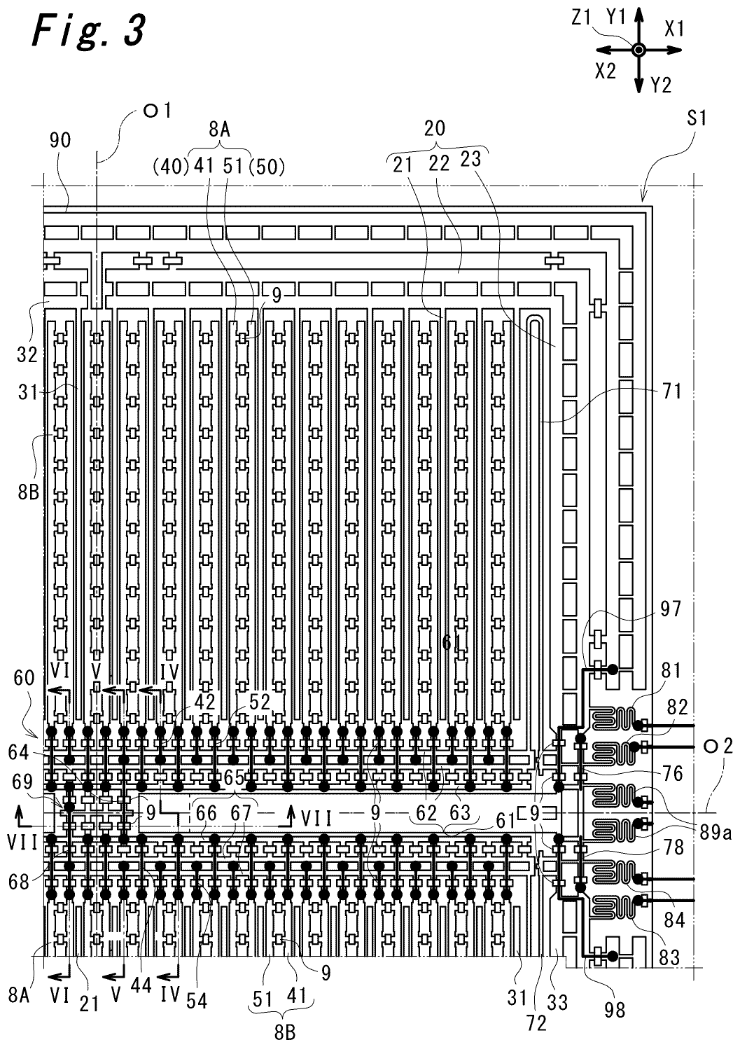

FIG. 3 is an enlarged plan view illustrating a periphery of the first region S1 of the sensor unit 3. First, a configuration of the MEMS electrode 6 in the first region S1 will be described with reference to FIG. 3. In the first region S1, the first fixed electrode 20 includes a plurality of first fixed electrode elements 21 extending in the Y direction and arranged in the X direction, a first fixed electrode base portion 22 connected to a Y1-side end portion of a plurality of the first fixed electrode elements 21 and extending in the X direction, and a first fixed electrode extension portion 23 extending from an end portion on the X1 side of the first fixed electrode base portion 22 to the Y2 side toward the Y-direction center line O2.

The first movable electrode 40 includes a plurality of first movable electrode elements 41 extending in the Y direction and arranged in the X direction. The second movable electrode 50 includes a plurality of second movable electrode elements 51 extending in the Y direction and arranged in the X direction. The first and second movable electrode elements 41 and 51 are alternately arranged in the X direction. In the first region S1, the first movable electrode element 41 and the second movable electrode element 51 located adjacent to the first movable electrode element 41 on the X1 side are connected to constitute a first set movable electrode element 8A.

An isolation joint 9 is used for connecting the first movable electrode element 41 and the second movable electrode element 51. The isolation joint 9 is, for example, silicon oxide formed by thermally oxidizing conductive silicon, and mechanically connects the two while electrically insulating the two.

In the first region S1, a plurality of the first fixed electrode elements 21 and a plurality of the first set movable electrode elements 8A are alternately arranged in the X direction while facing each other. Therefore, in the first region S1, the first movable electrode element 41 is located on the X1 side of the first fixed electrode element 21, and the second movable electrode element 51 is located on the X2 side of the first fixed electrode element 21. In the first region S1, the first fixed electrode element 21 and the first movable electrode element 41 constitute a first capacitor C1. Further, the first fixed electrode element 21 and the second movable electrode element 51 constitute a second capacitor C2.

In the first region S1, the movable electrode 8 further includes a first conductive path first portion 61 which is connected to a Y2-side end portion of a plurality of the first set movable electrode elements 8A via the isolation joint 9 and extends in the X direction over the first and third regions S1 and S3. The first conductive path portion 61 includes a first conductive path first portion 62 located on the Y1 side and a first conductive path second portion 63 located on the Y2 side. The first conductive path first portion 62 and the first conductive path second portion 63 are connected via the isolation joint 9.

In the present embodiment, the first conductive path portion 61 is configured in a ladder shape such that a portion extending in the X direction in three rows and a portion extending from each of the first and second movable electrode elements 41 and 51 to the Y2 side intersect, two rows on the Y1 side constitute the first conductive path first portion 62, and one row on the Y2 side constitutes the first conductive path second portion 63.

The first movable electrode element 41 and the first conductive path first portion 62 are electrically connected via a first wiring layer 42. FIG. 4 is a cross-sectional view taken along the first wiring layer 42 in line IV-IV of FIG. 3. As illustrated in FIG. 4, the first wiring layer 42 is formed on the insulating film 18 laminated on a surface on the Z1 side of the first movable electrode element 41 and the first conductive path first portion 62, and is electrically connected to the first movable electrode element 41 and the first conductive path first portion 62 via a first contact 43 penetrating the insulating film 18 in the Z direction.

Similarly, as illustrated in FIG. 3, the second movable electrode element 51 and the first conductive path second portion 63 are electrically connected via a second wiring layer 52. The second wiring layer 52 is formed on the insulating film 18 laminated on a surface on the Z side of the second movable electrode element 51 and the first conductive path second portion 63, and is electrically connected to the second movable electrode element 51 and the first conductive path second portion 63 via a second contact 53 (see FIG. 5) penetrating the insulating film 18 in the Z direction.

The first wiring layer 42 is formed at a position corresponding to the first movable electrode element 41 in the X direction. The second wiring layer 52 is formed at a position corresponding to the second movable electrode element 51 in the X direction. Therefore, the first wiring layer 42 and the second wiring layer 52 are alternately arranged in the X direction. The first and second wiring layers 42 and 52 are made from conductive metal, for example, aluminum.

The movable electrode 8 further includes a first spring portion 71 which is connected to an X1-side end portion of the first conductive path portion 61 and is configured to be elastically deformable in the X direction. The first spring portion 71 is electrically conductive and mechanically connected to the first conductive path first portion 62 of the first conductive path portion 61. The first spring portion 71 is located between the first fixed electrode element 21 located closest to the X1 side among a plurality of the first fixed electrode elements 21 and the first fixed electrode extension portion 23.

The movable electrode 8 further includes a first conductive path base portion 76 conductively and mechanically connected to the X1 side of the first spring portion 71. In the first conductive path base portion 76, a tip portion of the first fixed electrode extension portion 23 is connected to the Y1 side via the isolation joint 9.

Next, a configuration of the MEMS electrode 6 in the second region S2 will be described with reference to FIGS. 2 and 3. In the second region S2, the second fixed electrode 30 includes a plurality of second fixed electrode elements 31 extending in the Y direction and arranged in the X direction, a second fixed electrode base portion 32 connected to a Y2-side end portion of a plurality of the second fixed electrode elements 31 and extending in the X direction, and a second fixed electrode extension portion 33 extending from an end portion on the X1 side of the second fixed electrode base portion 32 to the Y1 side toward the Y-direction center line O2.

In the second region S2 as well, similarly to the first region S1, the first and second movable electrode elements 41 and 51 are alternately arranged in the X direction, but arrangement order of the first and second movable electrode elements 41 and 51 is different from that in the first region S1. Specifically, in the second region S2, the first movable electrode element 41 and the second movable electrode element 51 located adjacent to the first movable electrode element 41 on the X2 side constitute a second set movable electrode element 8B mechanically connected via the isolation joint 9.

A plurality of the second set movable electrode elements 8B are formed at positions corresponding to the first set movable electrode elements 8A in the first region S1 in the X direction. That is, the first movable electrode element 41 in the first region S1 and the second movable electrode element 51 in the second region S2 face each other in the Y direction across the Y-direction center line O2. Further, the second movable electrode element 51 in the first region S1 and the first movable electrode element 41 in the second region S2 face each other in the Y direction across the Y-direction center line O2.

In the second region S2, a plurality of the second fixed electrode elements 31 and a plurality of the second set movable electrode elements 8B are alternately arranged in the X direction while facing each other. Therefore, in the second region S2, the first movable electrode element 41 is located on the X2 side of the second fixed electrode element 31, and the second fixed electrode element 31 and the first movable electrode element 41 constitute a third capacitor C3. Further, the second movable electrode element 51 is located on the X1 side of the second fixed electrode element 31, and the second fixed electrode element 31 and the second movable electrode element 51 constitute a fourth capacitor C4.

In the second region S2, the movable electrode 8 further includes a second conductive path portion 65 which is connected to a Y1-side end portion of a plurality of the second set movable electrode elements 8B via the isolation joint 9 and extends in the X direction over the second and fourth regions S2 and S4. The second conductive path portion 65 includes a second conductive path first portion 66 located on the Y1 side and a second conductive path second portion 67 located on the Y2 side. The second conductive path first portion 66 and the second conductive path second portion 67 are connected via the isolation joint 9.

In the present embodiment, the second conductive path portion 65 is configured in a ladder shape such that a portion extending in the X direction in three rows and a portion extending from each of the first and second fixed electrode elements 21 and 31 to the Y1 side intersect, one row on the Y1 side constitutes the second conductive path first portion 66, and two rows on the Y2 side constitute the second conductive path second portion 67.

The first movable electrode element 41 and the second conductive path first portion 66 are electrically connected via a third wiring layer 44. As illustrated in FIG. 4, the third wiring layer 44 is formed on the insulating film 18 laminated on a surface on the Z1 side of the first movable electrode element 41 and the second conductive path first portion 66, and is electrically connected to the first movable electrode element 41 and the second conductive path first portion 66 via a third contact 45 penetrating the insulating film 18 in the Z direction.

Similarly, as illustrated in FIG. 3, the second movable electrode element 51 and the second conductive path second portion 67 are electrically connected via a fourth wiring layer 54. The fourth wiring layer 54 is formed on the insulating film 18 laminated on a surface on the Z side of the second movable electrode element 51 and the second conductive path second portion 67, and is electrically connected to the second movable electrode element 51 and the second conductive path second portion 67 via a fourth contact 55 (see FIG. 5) penetrating the insulating film 18 in the Z direction.

The third wiring layer 44 is formed at a position corresponding to the first movable electrode element 41 in the X direction. The fourth wiring layer 54 is formed at a position corresponding to the second movable electrode element 51 in the X direction. Therefore, the third wiring layer 44 and the fourth wiring layer 54 are alternately arranged in the X direction. The third and fourth wiring layers 44 and 54 are made from conductive metal, for example, aluminum.

The movable electrode 8 further includes a second spring 72 which is connected to an X1-side end portion of the second conductive path portion 65 and is configured to be elastically deformable in the X direction. The second spring portion 72 is electrically conductive and mechanically connected to the second conductive path second portion 67 of the second conductive path portion 65. The second spring portion 72 is located between the second fixed electrode element 31 located closest to the X1 side among a plurality of the second fixed electrode elements 31 and the second fixed electrode extension portion 33.

The movable electrode 8 further includes a second conductive path base portion 78 conductively and mechanically connected to the X1 side of the second spring portion 72. In the second conductive path base portion 78, a tip portion of the second fixed electrode extension portion 33 is connected to the Y2 side via the isolation joint 9.

Next, referring to FIGS. 2 and 3, a configuration of the MEMS electrode 6 in the third region S3 will be described. The second fixed electrode 30 is configured to be point-symmetric with respect to the center O with respect to the second fixed electrode 30 in the second region S2. The first and second movable electrode elements 41 and 51 are configured similarly to the first and second movable electrode elements 41 and 51 in the second region S2. As described above, in the third region S3, the first conductive path portion 61 extends in the X direction from the first region S1 to the third region S3.

Specifically, in the third region S3, the second fixed electrode 30 includes a plurality of the second fixed electrode elements 31 extending in the Y direction and arranged in the X direction, the second fixed electrode base portion 32 connected to a Y1-side end portion of a plurality of the second fixed electrode elements 31 and extending in the X direction, and the second fixed electrode extension portion 33 extending from an end portion on the X2 side of the second fixed electrode base portion 32 to the Y2 side toward the Y-direction center line O2.

The first and second movable electrode elements 41 and 51 are alternately arranged in the X direction. Specifically, in the third region S3, the first movable electrode element 41 and the second movable electrode element 51 located adjacent to the first movable electrode element 41 on the X2 side constitute the second set movable electrode element 8B mechanically connected via the isolation joint 9.

In the third region S3, a plurality of the second fixed electrode elements 31 and a plurality of the second set movable electrode elements 8B are alternately arranged in the X direction while facing each other. Therefore, in the third region S3, the first movable electrode element 41 is located on the X2 side of the second fixed electrode element 31, and the second fixed electrode element 31 and the first movable electrode element 41 constitute the third capacitor C3. Further, the second movable electrode element 51 is located on the X1 side of the second fixed electrode element 31, and the second fixed electrode element 31 and the second movable electrode element 51 constitute a fourth capacitor C4.

In the third region S3, similarly to the first region S1, each of the first movable electrode elements 41 is electrically connected to the first conductive path first portion 62 via the first wiring layer 42, and each of the second movable electrode elements 51 is electrically connected to the first conductive path second portion 63 via the second wiring layer 52.

The movable electrode 8 further includes a third spring portion 73 which is connected to an X2-side end portion of the first conductive path portion 61 and is configured to be elastically deformable in the X direction. The third spring portion 73 is electrically conductive and mechanically connected to the first conductive path first portion 62 of the first conductive path portion 61. The third spring portion 73 is located between the second fixed electrode element 31 located closest to the X2 side among a plurality of the second fixed electrode elements 31 and the second fixed electrode extension portion 33.

The movable electrode 8 further includes the first conductive path base portion 76 conductively and mechanically connected to the X2 side of the third spring portion 73. In the first conductive path base portion 76, a tip portion of the second fixed electrode extension portion 33 is connected to the Y1 side via the isolation joint 9.

Next, referring to FIGS. 2 and 3, a configuration of the MEMS electrode 6 in the fourth region S4 will be described. The first fixed electrode 20 is configured to be point-symmetric with respect to the center O with respect to the first fixed electrode 20 in the first region S1. The first and second movable electrode elements 41 and 51 are configured similarly to the first and second movable electrode elements 41 and 51 in the first region S1. As described above, in the fourth region S4, the second conductive path portion 65 extends in the X direction from the second region S2 to the fourth region S4.

Specifically, in the fourth region S4, the first fixed electrode 20 includes a plurality of the first fixed electrode elements 21 extending in the Y direction and arranged in the X direction, the first fixed electrode base portion 22 connected to a Y2-side end portion of a plurality of the first fixed electrode elements 21 and extending in the X direction, and the first fixed electrode extension portion 23 extending from an end portion on the X2 side of the first fixed electrode base portion 22 to the Y1 side toward the Y-direction center line O2.

The first and second movable electrode elements 41 and 51 are alternately arranged in the X direction. Specifically, in the fourth region S4, the first movable electrode element 41 and the second movable electrode element 51 located adjacent to the first movable electrode element 41 on the X1 side constitute the first set movable electrode element 8A mechanically connected via the isolation joint 9.

A plurality of the first set movable electrode elements 8A are formed at positions corresponding to the second set movable electrode elements 8B in the third region S3 in the X direction. That is, the first movable electrode element 41 in the third region S3 and the second movable electrode element 51 in the fourth region S4 face each other in the Y direction across the Y-direction center line O2. Further, the second movable electrode element 51 in the third region S3 and the first movable electrode element 41 in the fourth region S4 face each other in the Y direction across the Y-direction center line O2.

In the fourth region S4, a plurality of the first fixed electrode elements 21 and a plurality of the first set movable electrode elements 8A are alternately arranged in the X direction while facing each other. Therefore, in the fourth region S4, the first movable electrode element 41 is located on the X1 side of the first fixed electrode element 21, and the first fixed electrode element 21 and the first movable electrode element 41 constitute the first capacitor C1. Further, the second movable electrode element 51 is located on the X2 side of the first fixed electrode element 21, and the first fixed electrode element 21 and the second movable electrode element 51 constitute the second capacitor C2.

In the fourth region S4, similarly to the second region S2, each of the first movable electrode elements 41 is electrically connected to the second conductive path first portion 66 via the third wiring layer 44, and each of the second movable electrode elements 51 is electrically connected to the second conductive path second portion 67 via the fourth wiring layer 54.

The movable electrode 8 further includes a fourth spring portion 74 which is connected to an X2-side end portion of the second conductive path portion 65 and is configured to be elastically deformable in the X direction. The fourth spring portion 74 is electrically conductive and mechanically connected to the second conductive path second portion 67 of the second conductive path portion 65. The fourth spring portion 74 is located between the first fixed electrode element 21 located closest to the X2 side among a plurality of the first fixed electrode elements 21 and the first fixed electrode extension portion 23.

The movable electrode 8 further includes the second conductive path base portion 78 conductively and mechanically connected to the X2 side of the fourth spring portion 74. In the second conductive path base portion 78, a tip portion of the second fixed electrode extension portion 33 is connected to the Y2 side via the isolation joint 9.

As illustrated in FIG. 3, the first conductive path portion 61 and the second conductive path portion 65 are located to be separated from each other on both sides in the Y direction across the X-direction center line O1. The first conductive path portion 61 and the second conductive path portion 65 are mechanically connected to each other in the Y direction by a conductive path connection portion 69 at a center portion in the X direction. The first conductive path portion 61, the second conductive path portion 65, and the conductive path connection portion 69 constitute an H-shaped conductive path portion 60.

The conductive path connection portion 69 is located at the center O, and is configured to have a rectangular shape elongated in the X direction in a region extending over the first to fourth regions S1 to S4. The conductive path connection portion 69 is connected to each of the first conductive path portion 61 and the second conductive path portion 65 via the isolation joint 9.

In the conductive path connection portion 69, a connection portion first wiring layer 64 electrically connecting the first conductive path first portion 62 and the second conductive path first portion 66, and a connection portion second wiring layer 68 electrically connecting the first conductive path second portion 63 and the second conductive path second portion 67 are formed. The connection portion first wiring layer 64 extends over the first and second regions S1 and S2 in the conductive path connection portion 69, and is formed at a position corresponding to the first movable electrode element 41 in the first region S1 in the X direction. The connection portion second wiring layer 68 extends over the third and fourth regions S3 and S4 in the conductive path connection portion 69, and is formed at a position corresponding to the second movable electrode element 51 in the fourth region S4 in the X direction.

FIG. 5 is a cross-sectional view taken along the connection portion first wiring layer 64 along line V-V in FIG. 3. As illustrated in FIG. 5, the connection portion first wiring layer 64 is formed on the insulating film 18 laminated on the conductive path connection portion 69, extends to the Y2 side continuously to the first wiring layer 42 formed on the first conductive path first portion 62, and is electrically connected to the second conductive path first portion 66 via a fifth contact 56.

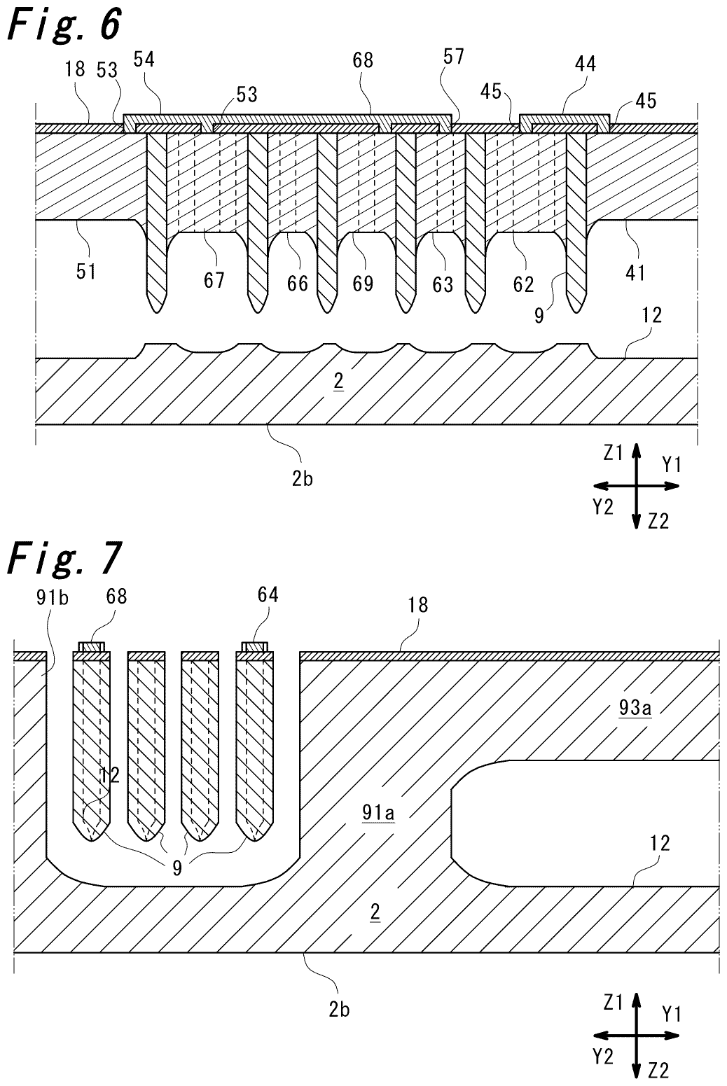

FIG. 6 is a cross-sectional view taken along the connection portion second wiring layer 68 along line VI-VI in FIG. 3. As illustrated in FIG. 6, the connection portion second wiring layer 68 is formed on the insulating film 18 laminated on the conductive path connection portion 69, extends to the Y1 side continuously to the fourth wiring layer 54 formed on the second conductive path second portion 67, and is electrically connected to the first conductive path second portion 63 via a sixth contact 57.

In the movable electrode 8, the H-shaped conductive path portion 60 constitutes a proof mass. That is, a plurality of the first movable electrode elements 41 and a plurality of the second movable electrode elements 51 are connected to a single proof mass.

### (Configuration of Frame)

Next, the frame 90 that supports the MEMS electrode 6 will be described. The MEMS electrode 6 in a state of being supported by the frame 90 is in a state of floating from the recessed portion bottom surface 12 of the recessed portion 10, that is, is separated from the recessed portion bottom surface 12 toward the Z1 side, and is not rigidly connected to any of the recessed portion first to fourth side surfaces 13 to 16. Here, “rigidly connected” in the present specification means not including a connection that allows a certain degree of elastic displacement via an elastic element such as a flexible lead described later but being rigidly connected without allowing active displacement.

As indicated by a broken line in FIG. 1, the frame 90 includes an anchor 91 provided in an anchor region R which is a partial region of the recessed portion bottom surface 12, and a suspension frame 92 connected to the anchor 91 and supporting the MEMS electrode 6. The suspension frame 92 includes an anchor connection frame 93 extending in the X direction from the anchor 91 and a base frame 94 located around the MEMS electrode 6.

FIG. 7 is a cross-sectional view taken along the X direction of the anchor 91 along line VII-VII of FIG. 3. As illustrated in FIG. 7, the anchor 91 projects from the recessed portion bottom surface 12 toward the Z1 side. In other words, the anchor 91 is formed integrally with the recessed portion bottom surface 12 in the anchor region R that is a partial region of the recessed portion bottom surface 12. As indicated by a two-dot chain line in FIG. 1, the anchor region R is a region including the center O in plan view in the recessed portion bottom surface 12. More specifically, the center position in plan view of the anchor region R coincides with the center O. A width dimension in the X direction of the anchor region R is 2.5 μm or more and 25 μm or less, and is, for example, m in the present embodiment.

In the present embodiment, the anchors 91 are provided in a pair on both sides sandwiching the conductive path connection portion 69 in the X direction, and include a first anchor 91a located on the X1 side of the conductive path connection portion 69 and a second anchor 91b located on the X2 side.

The anchor connection frame 93 is separated from the recessed portion bottom surface 12 toward the Z1 side, and is not rigidly connected to any of a plurality of the recessed portion wall surfaces 11. As illustrated in FIG. 1, the anchor connection frame 93 is formed integrally with the anchor 91, and includes a first connection frame 93a extending from the first anchor 91a to the X1 side and a second connection frame 93b extending from the second anchor 91b to the X2 side.

The first connection frame 93a extends to positions corresponding to the first conductive path base portion 76 located in the first region S1 and the second conductive path base portion 78 located in the second region S2 in the X direction, and is connected to each of the first and second conductive path base portions 76 and 78 via the isolation joint 9. On the other hand, the second connection frame 93b extends to positions corresponding to the first conductive path base portion 76 located in the third region S3 and the second conductive path base portion 78 located in the fourth region S4 in the X direction, and is connected to each of the first and second conductive path base portions 76 and 78 via the isolation joint 9.

The base frame 94 is separated from the recessed portion bottom surface 12 toward the Z1 side, and is not connected to any of the recessed portion first to fourth side surfaces 13 to 16. The base frame 94 includes a first base frame 95 having a substantially U shape with an opening on the Y2 side so as to surround the MEMS electrode 6 from the Y1 side in plan view, and a second base frame 96 having a substantially U shape with an opening on the Y1 side so as to surround the MEMS electrode 6 from the Y2 side.

The first base frame 95 includes a first frame first portion 95a located on the Y1 side of the MEMS electrode 6 and extending in the X direction along the recessed portion second side surface 14 over the first and third regions S1 and S3, a first frame second portion 95b located on the X1 side of the MEMS electrode 6 and extending in the Y direction along the recessed portion first side surface 13, and a first frame third portion 95c located on the X2 side of the MEMS electrode 6 and extending in the Y2 side along the recessed portion third side surface 15.

Referring also to FIG. 2, the first frame first portion 95a is connected to the first fixed electrode base portion 22 and the second fixed electrode base portion 32 via the isolation joint 9. In the present embodiment, the isolation joints 9 are provided at one place in an X1-side end portion and two places in an X2-side end portion of the first fixed electrode base portion 22, and are provided at two places in an X1-side end portion and one place in an X2-side end portion of the second fixed electrode base portion 32.

The first frame second portion 95b extends from an X1-side end portion of the first frame first portion 95a to the Y2 side and extends to immediately before a first flexible lead 81 described later. The first frame second portion 95b is connected to the first fixed electrode extension portion 23 via the isolation joint 9. In the present embodiment, the isolation joint 9 is provided at one place of a Y1-side end portion and two places of a Y2-side end portion of the first fixed electrode extension portion 23.

The first frame third portion 95c extends from an end portion on the X2 side of the first frame first portion 95a to the Y2 side, and extends to immediately before a fifth flexible lead 85 described later. The first frame third portion 95c is connected to the second fixed electrode extension portion 33 via the isolation joint 9. In the present embodiment, the isolation joint 9 is provided at one place of a Y1-side end portion and two places of a Y2-side end portion of the second fixed electrode extension portion 33.

Note that, as illustrated in FIG. 3, the first frame second portion 95b is electrically connected to the first connection frame 93a via a fifth wiring layer 97 formed on the insulating film 18. Similarly, although not illustrated, the first frame third portion 95c is electrically connected to the second connection frame 93b via a wiring layer formed on the insulating film 18. Therefore, the first base frame 95 is electrically connected to the first connection frame 93a or the second connection frame 93b, and is set to the same potential as the anchor connection frame 93.

As illustrated in FIG. 1, the second base frame 96 includes a second frame first portion 96a located on the Y2 side of the MEMS electrode 6 and extending in the X direction along the recessed portion fourth side surface 16 over the second and fourth regions S2 and S4, a second frame second portion 96b located on the X1 side of the MEMS electrode 6 and extending in the Y direction along the recessed portion first side surface 13, and a second frame third portion 96c located on the X2 side of the MEMS electrode 6 and extending in the Y direction along the recessed portion third side surface 15.

Referring also to FIG. 2, the second frame first portion 96a is connected to the first fixed electrode base portion 22 and the second fixed electrode base portion 32 via the isolation joint 9. In the present embodiment, the isolation joints 9 are provided at two places in an X1-side end portion and one place in an X2-side end portion of the first fixed electrode base portion 22, and are provided at one place in an X1-side end portion and two places in an X2-side end portion of the second fixed electrode base portion 32.

The second frame second portion 96b extends from an end portion on the X1 side of the second frame first portion 96a to the Y1 side, and extends to immediately before a third flexible lead 83 to be described later. The second frame second portion 96b is connected to the second fixed electrode extension portion 33 via the isolation joint 9. In the present embodiment, the isolation joint 9 is provided at two places of a Y1-side end portion and one place of a Y2-side end portion of the second fixed electrode extension portion 33.

The second frame third portion 96c extends from an end portion on the X2 side of the second frame first portion 96a to the Y1 side, and extends to immediately before a seventh flexible lead 87 described later. The second frame third portion 96c is connected to the first fixed electrode extension portion 23 via the isolation joint 9. In the present embodiment, the isolation joint 9 is provided at two places of a Y1-side end portion and one place of a Y2-side end portion of the first fixed electrode extension portion 23.

Note that, as illustrated in FIG. 3, the second frame second portion 96b is electrically connected to the first connection frame 93a via a sixth wiring layer 98 formed on insulating film 18. Similarly, although not illustrated, the second frame third portion 96c is electrically connected to the second connection frame 93b via a wiring layer formed on the insulating film 18. Therefore, the second base frame 96 is electrically connected to the first connection frame 93a or the second connection frame 93b, and is set to the same potential as the anchor connection frame 93.

Support of the MEMS electrode 6 by the frame 90 will be summarized below.

The movable electrode 8 has an X1-side end portion (the first and second conductive path base portions 76 and 78 in the first and second regions S1 and S2) connected to the first connection frame 93a via the isolation joint 9, and an X2-side end portion (the first and second conductive path base portions 76 and 78 in the third and fourth regions S3 and S4) connected to the second connection frame 93b via the isolation joint 9.

The fixed electrode 7 has an X1-side end portion (the first and second fixed electrode extension portions 23 and 33 in the first and second regions S1 and S2) connected to the first and second conductive path base portions 76 and 78 of the movable electrode 8 via the isolation joint 9, and an X2-side end portion (the first and second fixed electrode extension portions 23 and 33 in the third and fourth regions S3 and S4) connected to the first and second conductive path base portions 76 and 78 of the movable electrode 8 via the isolation joint 9. Further, in the fixed electrode 7, the first and second fixed electrode base portions 22 and 32 are connected to the first frame first portion 95a or the second frame first portion 96a via the isolation joint 9.

Therefore, both the fixed electrode 7 and the movable electrode 8 are supported by the frame 90, are rigidly connected to the anchor region R of the recessed portion bottom surface 12 via the frame 90, and are not rigidly connected to any of another portion of the recessed portion bottom surface and another one of the recessed portion wall surfaces 11.

### (Configuration of Flexible Lead)

As illustrated in FIG. 2, the sensor unit 3 includes, in the first region S1, the first flexible lead 81 that connects, in the X direction, a Y2-side end portion of the first fixed electrode extension portion 23 and the recessed portion first side surface 13, and a second flexible lead 82 that connects, in the X direction, the first conductive path base portion 76 and the recessed portion first side surface 13. In the second region S2, the sensor unit 3 includes the third flexible lead 83 that connects, in the X direction, a Y1-side end portion of the second fixed electrode extension portion 33 and the recessed portion first side surface 13, and a fourth flexible lead 84 that connects, in the X direction, the second conductive path base portion 78 and the recessed portion first side surface 13.

In the third region S3, the sensor unit 3 includes the fifth flexible lead 85 that connects, in the X direction, a Y2-side end portion of the second fixed electrode extension portion 33 and the recessed portion third side surface 15, and a sixth flexible lead 86 that connects, in the X direction, the first conductive path base portion 76 and the recessed portion third side surface 15. In the fourth region S4, the sensor unit 3 includes the seventh flexible lead 87 that connects, in the X direction, a Y1-side end portion of the first fixed electrode extension portion 23 and the recessed portion third side surface 15, and an eighth flexible lead 88 that connects, in the X direction, the second conductive path base portion 78 and the recessed portion third side surface 15.

Further, the sensor unit 3 includes a ninth flexible lead 89a connecting, in the X direction, the first connection frame 93a and the recessed portion first side surface 13 between the second flexible lead 82 and the fourth flexible lead 84. Further, the sensor unit 3 includes a tenth flexible lead 89b that connects, in the X direction, the second connection frame 93b and the recessed portion third side surface 15 between the sixth flexible lead 86 and the eighth flexible lead 88. The ninth and tenth flexible leads 89a and 89b are provided as a pair across the Y-direction center line O2.

That is, the first to fourth and ninth flexible leads 81 to 84 and 89a are located on the X1 side of the MEMS electrode 6, and the fifth to eighth and tenth flexible leads 85 to 88 and 89b are located on the X2 side of the MEMS electrode 6.

Each of the first to tenth flexible leads 81 to 89b (hereinafter collectively referred to as the flexible lead 80 in some cases) is made from conductive silicon, and has bent portions bent by 180° at a plurality of places so as to have a portion reciprocating a plurality of times in the X direction and a portion reciprocating a plurality of times in the Y direction, and is configured to be stretchable in the X direction and the Y direction by being bent and deformed with these bent portions as starting points. The flexible lead 80 merely provides electrical connection from the outside of the recessed portion 10 to the sensor unit 3, and does not rigidly connect the sensor unit 3 to the recessed portion wall surface 11. The flexible lead 80 is electrically connected to the electrode pad 4 via wiring (not illustrated).

### (Circuit Configuration of MEMS Electrode)

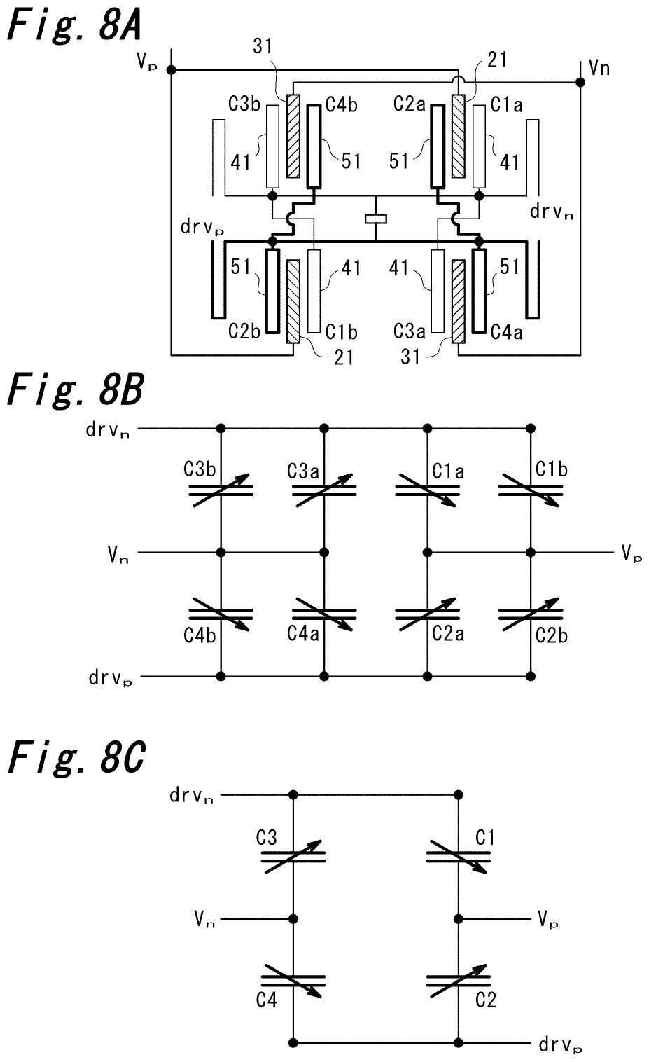

FIG. 8A is a simplified element diagram illustrating a circuit configuration of the MEMS electrode 6 in a simplified manner. As illustrated in FIG. 8A, a first capacitor C1a and a second capacitor C2a are configured in the first region S1, a third capacitor C3a and a fourth capacitor C4a are configured in the second region S2, a third capacitor C3b and a fourth capacitor C4b are configured in the third region S3, and a first capacitor C1b and a second capacitor C2b are configured in the fourth region S4. In the present embodiment, in each of the capacitors C1 to C4, a gaps between electrodes are set to be equal in a reference state where no acceleration acts, and thus, capacitances are equal.

Note that, in FIG. 8A, in order to distinguish between the first and second capacitors C1 and C2 located in the first and fourth regions S1 and S4, the first and second capacitors located in the first region S1 are denoted by C1a and C2a, and the first and second capacitors located in the fourth region S4 are denoted by C1b and C2b. Similarly, in FIG. 8A, in order to distinguish between the third and fourth capacitors C3 and C4 located in the second and third regions S2 and S3, the third and fourth capacitors located in the second region S2 are denoted by C3a and C4a, and the third and fourth capacitors located in the third region S3 are denoted by C3b and C4b.

In the present embodiment, acceleration is detected based on first output voltage Vp output from the first and seventh flexible leads 81 and 87 and second output voltage Vn output from the third and fifth flexible leads 83 and 85 when first input voltage drvn that is AC voltage is applied to the first conductive path base portion 76 via the second and sixth flexible leads 82 and 86 and second input voltage drvp that is AC voltage is applied to the second conductive path base portion 78 via the fourth and eighth flexible leads 84 and 88.

For example, in a case where the movable electrode 8 is displaced to the X2 side with respect to the fixed electrode 7 from the state illustrated in FIG. 8A, capacitance in the first and fourth capacitors C1 and C4 increases with a change in a gap between the fixed electrode 7 and the movable electrode 8, while capacitance in the second and third capacitors C2 and C3 decreases. Conversely, in a case where the movable electrode 8 is displaced to the X1 side with respect to the fixed electrode 7 from the state illustrated in FIG. 8A, capacitance in the first and fourth capacitors C1 and C4 decreases, while capacitance in the second and third capacitors C2 and C3 increases.

FIG. 8B is an equivalent circuit diagram illustrating each element of FIG. 8A. FIG. 8C illustrates the equivalent circuit diagram illustrated in FIG. 8B in a further simplified manner. As illustrated in FIG. 8C, when the first input voltage drvn and the second input voltage drvp symmetrical to the first input voltage drvn are applied to MEMS electrode 6, the first output voltage Vp and the second output voltage Vn symmetrical to the first output voltage Vp are output along with a change in capacitance of the first to fourth capacitors C1 to C4. At this time, the first output Vp and the second output Vn can similarly include common mode noise and the like.

Next, by calculating a difference between the first output voltage Vp and the second output voltage Vn, output in which common mode noise and the like are canceled can be obtained. Here, since the MEMS electrode 6 includes one proof mass, individual noise caused by individual variation of the proof mass can be included in both the first output voltage Vp and the second output voltage Vn in common. Therefore, by calculating a difference between the first output voltage Vp and the second output voltage Vn, it is possible to obtain output in which individual noise is canceled in addition to common mode noise and the like. Therefore, calculation accuracy of acceleration can be improved by calculating acceleration based on the output.

According to the acceleration sensor 1 according to the above embodiment, following effects are exhibited.

(1) The acceleration sensor 1 includes the device-side substrate 2 having the first main surface 2a and the second main surface 2b facing the first main surface 2a, the recessed portion 10 recessed from the first main surface 2a toward the second main surface 2b, the MEMS electrode 6 provided in the recessed portion 10, including the fixed electrode 7 having the first fixed electrode 20 and the second fixed electrode 30 electrically insulated from the first fixed electrode 20, and the movable electrode 8 having the first movable electrode 40 and the second movable electrode 50 electrically insulated from the first movable electrode 40, and constituting a differential circuit, and the isolation joint 9 mechanically connecting the first movable electrode 40 and the second movable electrode 50 while electrically insulating the first movable electrode 40 and the second movable electrode 50.

As a result, since the first movable electrode 40 and the second movable electrode 50 are mechanically connected to each other while being electrically insulated via the isolation joint 9, two movable electrodes having different potentials can be included in one proof mass that is integrally displaced. As a result, individual variation commonly occurs in the first movable electrode 40 and the second movable electrode 50, and thus, by obtaining a difference between two obtained output voltages, outputs in which individual noise caused by individual variation are canceled out from each other is obtained in addition to removal of common mode noises and the like. Therefore, calculation accuracy of acceleration can be improved based on output in which common mode noise and the like and individual noise are canceled.

(2) The first fixed electrode 20 includes a plurality of the first fixed electrode elements 21, the second fixed electrode 30 includes a plurality of the second fixed electrode elements 31, the first movable electrode 40 includes a plurality of the first movable electrode elements 41, and the second movable electrode 50 includes a plurality of the second movable electrode elements 51. The MEMS electrode 6 includes the first capacitor C1 including a plurality of the first fixed electrode elements 21 and a plurality of the first movable electrode elements 41 facing each of the first fixed electrode elements 21 in the X direction, the second capacitor C2 including a plurality of the first fixed electrode elements 21 and a plurality of the second movable electrode elements 51 facing each of the first fixed electrode elements 21 in the X direction, the third capacitor C3 including a plurality of the second fixed electrode elements 31 and a plurality of the first movable electrode elements 41 facing each of the second fixed electrode elements 31 in the X direction, and the fourth capacitor C4 including a plurality of the second fixed electrode elements 31 and a plurality of the second movable electrode elements 51 facing each of the second fixed electrode elements 31 in the X direction. When the first movable electrode 40 and the second movable electrode 50 are displaced in the X direction in a state where the input voltages drvn and drvp having opposite phases to each other are input to the first movable electrode 40 and the second movable electrode 50, the output voltages Vp and Vn having opposite phases to each other are output from the first fixed electrode 20 and the second fixed electrode 30.

That is, in a fully differential acceleration sensor, the above effect is suitably exhibited.

(3) In plan view, the MEMS electrode 6 includes the first capacitor C1 and the second capacitor C2 in the first region S1 located on the Y1 side, and includes the third capacitor C3 and the fourth capacitor C4 in the second region S2 located on the Y2 side. In the first region S1, the first movable electrode element 41 and the second movable electrode element 51 arranged adjacent to the X1 side of the first movable electrode element 41 are connected to each other via the isolation joint 9, and these constitute the first set movable electrode element 8A. Each of a plurality of the first set movable electrode elements 8A and each of a plurality of the first fixed electrode elements 21 are alternately arranged in the X direction. In the second region S2, the first movable electrode element 41 and the second movable electrode element 51 arranged adjacent to the X2 side of the first movable electrode element 41 are connected to each other via the isolation joint 9, and these constitute the second set movable electrode element 8B. Each of a plurality of the second set movable electrode elements 8B and each of a plurality of the second fixed electrode elements 31 are alternately arranged in the X direction.

As a result, when the movable electrode 8 is displaced in the X direction, increase and decrease of capacitance in the first capacitor C1 and the third capacitor C3 and increase and decrease of capacitance in the second capacitor C2 and the fourth capacitor C4 are symmetrical, so that a fully differential MEMS acceleration sensor can be constituted by the first to fourth capacitors C1 to C4.

(4) The movable electrode 8 further includes the conductive path portion 60 extending in the X direction between a plurality of the first set movable electrode elements 8A and a plurality of the second set movable electrode elements 8B. As a result, the conductive path portion 60 can be compactly arranged between the first set movable electrode element 8A and the second set movable electrode elements 8B.

(5) The conductive path portion 60 includes the first conductive path portion 61 mechanically connected to a plurality of the first set movable electrode elements 8A and the second conductive path portion 65 mechanically connected to a plurality of the second set movable electrode elements 8B.

As a result, the first conductive path portion 61 electrically connected to the first set movable electrode element 8A and the second conductive path portion 65 electrically connected to the second set movable electrode element 8B are individually configured in the conductive path portion 60, so that circuit connection of the conductive path portion 60 can be simplified.

(6) The first conductive path portion 61 includes the first conductive path first portion 62 electrically connected to the first movable electrode element 41 and the first conductive path second portion 63 electrically connected to the second movable electrode element 51. The second conductive path portion 65 includes the second conductive path first portion 66 electrically connected to the first movable electrode element 41 and the second conductive path second portion 67 electrically connected to the second movable electrode element 51. The first conductive path first portion 62 and the second conductive path first portion 66 are electrically connected, and the first conductive path second portion 63 and the second conductive path second portion 67 are electrically connected.

As a result, the first movable electrode elements 41 located in different regions (for example, the first region S1 and the second region S2) can be electrically connected to each other over the first conductive path portion 61 and the second conductive path portion 65 and the second movable electrode elements 51 located in different regions (for example, the first region S1 and the second region S2) can be electrically connected to each other over the first conductive path portion 61 and the second conductive path portion 65, so that circuit connection of the conductive path portion 60 can be simplified.

(7) The first conductive path first portion 62 and the first conductive path second portion 63 are connected via the isolation joint 9. The second conductive path first portion 66 and the second conductive path second portion 67 are connected via the isolation joint 9.

As a result, the first conductive path first portion 62 and the first conductive path second portion 63 can be configured as one proof mass, and the second conductive path first portion 66 and the second conductive path second portion 67 can be configured as one mass.

(8) The first conductive path portion 61 and the second conductive path portion 65 are connected via the isolation joint 9.

As a result, the first conductive path portion 61 and the second conductive path portion 65 can be configured as one proof mass.

(9) The first conductive path first portion 62 and the second conductive path first portion 66 are electrically connected via the connection portion first wiring layer 64. The first conductive path second portion 63 and the second conductive path second portion 67 are electrically connected via the connection portion second wiring layer 68.

As a result, while the first conductive path portion 61 and the second conductive path portion 65 are configured as one proof mass, the first movable electrode elements 41 included in each region can be electrically connected to each other while insulation with respect to the second movable electrode element 51 is maintained, and the second movable electrode elements 51 included in each region can be electrically connected to each other while insulation with respect to the first movable electrode element 41 is maintained.

(10) The first conductive path portion 61 includes the first and third spring portions 71 and 73 that are elastically deformed in the X direction at both end portions in the X direction. The second conductive path portion 65 includes the second and fourth spring portions 72 and 74 that are elastically deformed in the X direction at both end portions in the X direction.

As a result, a pair of the spring portions 71 to 74 are provided in the Y direction on each of both sides in the X direction of the conductive path portion 60. Therefore, the first set movable electrode element 8A and the second set movable electrode element 8B can be elastically and stably supported by a pair of the common spring portions 71 to 74 provided in the Y direction on each of both sides in the X direction. Therefore, the structure can be simplified as compared with a case where a pair of spring portions are individually provided in the Y direction for each of the first set movable electrode element 8A and the second set movable electrode element 8B.

(11) In the recessed portion 10, in plan view, the third region S3 adjacent to the first region S1 in the X direction and the fourth region S4 adjacent to the second region S2 in the X direction and adjacent to the third region S3 in the Y direction are further included, and the first and second capacitors C1 and C2 are located also in the fourth region S4 in addition to the first region S1, and the third and fourth capacitors C3 and C4 are located in the third region S3 in addition to the second region S2.

As a result, the first to fourth capacitors C1 to C4 are arranged diagonally in the recessed portion 10. As a result, since variations of a pair of capacitors arranged diagonally occur in opposite directions, noises caused by the variations are suppressed by canceling each other.

(12) The acceleration sensor 1 includes the device-side substrate 2 having the first main surface 2a and the second main surface 2b facing the first main surface 2a, the recessed portion 10 recessed from the first main surface 2a toward the second main surface 2b and defined by a plurality of the recessed portion wall surfaces 11, the anchor 91 projecting from the anchor region R which is a partial region of any one of a plurality of the recessed portion wall surfaces 11, the suspension frame 92 having one end portion connected to the anchor 91 and extending in the recessed portion 10 and separated from a plurality of the recessed portion wall surfaces 11, the MEMS electrode 6 located in the recessed portion 10, and the isolation joint 9 mechanically connecting the MEMS electrode 6 to the suspension frame 92 while electrically insulating the MEMS electrode 6 from the suspension frame 92.

Here, in general, an acceleration sensor is mounted on a printed circuit board or the like in a state of being accommodated in a package, and is used by being incorporated in various devices. In the package, package stress may be generated when the package is mounted on a printed circuit board or the like and/or when the package is incorporated into/used in a device. As a result, when the package stress is transmitted to the acceleration sensor, distortion occurs in the acceleration sensor, and a characteristic of the acceleration sensor may change. That is, there is a problem in providing an acceleration sensor in which distortion due to package stress can be suppressed.

On the other hand, in the acceleration sensor 1, since the suspension frame 92 is supported by the anchor 91 with respect to the anchor region R, package stress (distortion) that may occur in the device-side substrate 2 is transmitted to the MEMS electrode 6 supported by the suspension frame 92 via the anchor 91 and the suspension frame 92. As a result, as compared with a case where package stress is transmitted from a plurality of places in a case where the MEMS electrode 6 is supported at a plurality of the places with respect to the recessed portion wall surface 11, distortion that may occur in the MEMS electrode 6 can be easily minimized. Therefore, it is easy to stabilize detection by the acceleration sensor 1.

(13) The anchor region R is located on the recessed portion bottom surface 12. As a result, it is easy to support the suspension frame 92 in a balanced manner by the anchor 91 provided on the recessed portion bottom surface 12 as compared with a case where the anchor 91 is provided on any one of the recessed portion first to fourth side surfaces 13 to 16.

(14) The anchor region R has a width dimension in the X direction of 2.5 μm or more and 25 μm or less.

As a result, it is easy to reduce stress transmitted from the device-side substrate 2 to the suspension frame 92 via the anchor 91. In a case where a width dimension of the anchor region R in the X direction is less than 2.5 μm, it is difficult to secure support rigidity of the suspension frame 92 by the anchor 91. On the other hand, in a case where a width dimension in the X direction of the anchor region R exceeds 25 μm, stress transmitted from a device-side substrate to the suspension frame 92 via the anchor 91 tends to be large, the MEMS electrode 6 tends to be complicatedly distorted, and thus noise in measurement by the acceleration sensor 1 tends to increase.

(15) The anchor region R includes the center O in plan view of the recessed portion bottom surface.

As a result, the suspension frame 92 can be more easily supported in a balanced manner by the anchor 91, and stress that may be generated in the MEMS electrode 6 due to the support can be easily suppressed.

(16) The center of the anchor 91 in plan view coincides with the center O of the recessed portion bottom surface.

As a result, the suspension frame 92 can be more easily supported by the anchor 91 in a more balanced manner, and stress that may be generated in the MEMS electrode 6 due to the support can be more easily suppressed.

(17) The suspension frame 92 includes the anchor connection frame 93 extending from the anchor 91 toward the recessed portion wall surface 11, and the base frame 94 directly or indirectly rigidly connected to the anchor connection frame 93 and extending along a plurality of the recessed portion wall surfaces 11 around MEMS electrode 6.

As a result, while the anchor 91 is provided in the anchor region R of the recessed portion bottom surface 12, the base frame 94 can be easily configured to be separated from the anchor 91 by the anchor connection frame 93 and to extend along the recessed portion wall surface 11. By the above, it is easy to secure a wide space in which the MEMS electrode 6 is arranged inside the base frame 94.

(18) The MEMS electrode 6 is supported by the base frame 94.

As a result, the MEMS electrode 6 arranged inside the base frame 94 can be suitably supported by the base frame.

(19) The anchor 91 includes the first anchor 91a and a second anchor 91b separated from the first anchor 91a.

As a result, the anchor 91 can be configured separately as the first anchor 91a and the second anchor 91b, and degree of freedom in design can be improved.

(20) The movable electrode 8 further includes the conductive path portion 60 connected to a plurality of the first and second movable electrode elements 41 and 51, and the conductive path portion 60 has a portion extending in the Y direction intersecting the X direction in which the first anchor 91a and the second anchor 91b are arranged, between the first anchor 91a and the second anchor 91b.

As a result, the conductive path connection portion 69 that connects the first conductive path portion 61 and the second conductive path portion 65 can be compactly arranged using a space between the first anchor 91a and the second anchor 91b.

(21) The fixed electrode 7 and the movable electrode 8 are connected to the recessed portion wall surface 11 via the flexible lead 80 that is conductive and is elastically deformable.

As a result, while the MEMS electrode 6 supported by the suspension frame 92 is electrically connected to the device-side substrate 2 via the flexible lead 80, transmission of stress/distortion from the device-side substrate 2 to the MEMS electrode 6 is suppressed. Therefore, since distortion that may occur in the MEMS electrode 6 is suppressed, it is easy to stabilize detection accuracy by the acceleration sensor.

### Second Embodiment

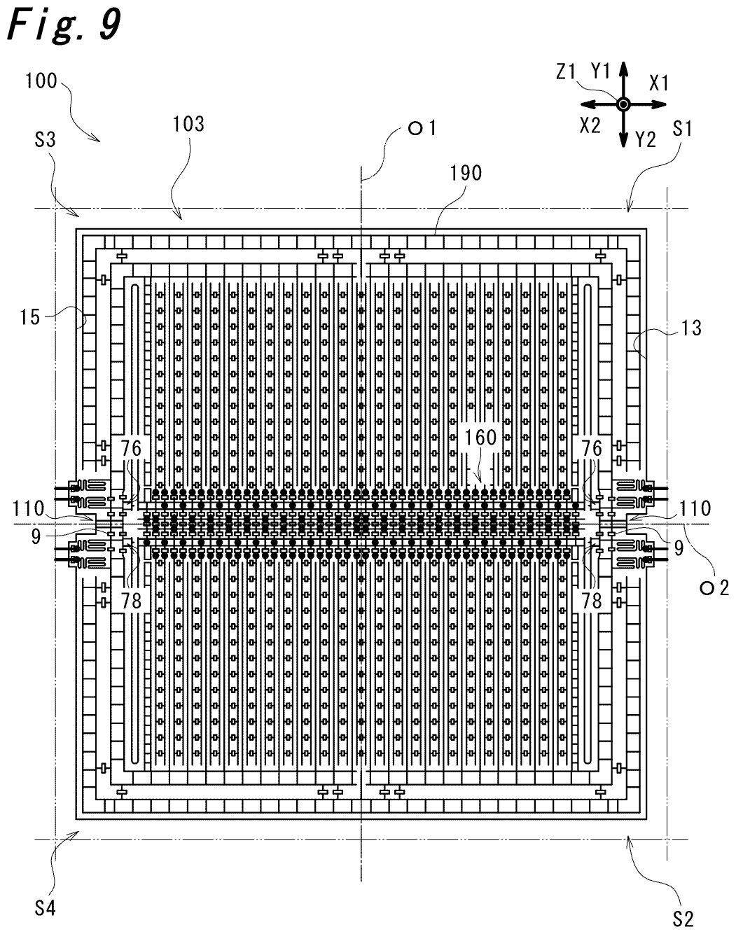

FIG. 9 is an enlarged plan view similar to FIG. 2 illustrating a sensor unit 103 of an acceleration sensor 100 according to a second embodiment of the present disclosure. As illustrated in FIG. 9, the sensor unit 103 is different from the sensor unit 3 of the first embodiment in a configuration of a conductive path portion 160 and a frame 190. Components common to the sensor unit 3 are denoted by the same reference numerals, and explanation thereof will be omitted.

The frame 190 is different from the frame 90 of the first embodiment in not including the anchor 91 and the anchor connection frame 93, but instead including a pair of recessed portion wall surface connection portions 110 that connect a MEMS electrode 106 to each of the first and third recessed portion side surfaces 13 and 15.

A pair of the recessed portion wall surface connection portions 110 are located between the first conductive path base portion 76 and the second conductive path base portion 78 on both sides on the X1 side and the X2 side of the MEMS electrode 106, and are connected to these via the isolation joint 9. Furthermore, each of a pair of the recessed portion wall surface connection portions 110 is connected to the first recessed portion side surface 13 or the third recessed portion side surface 15.

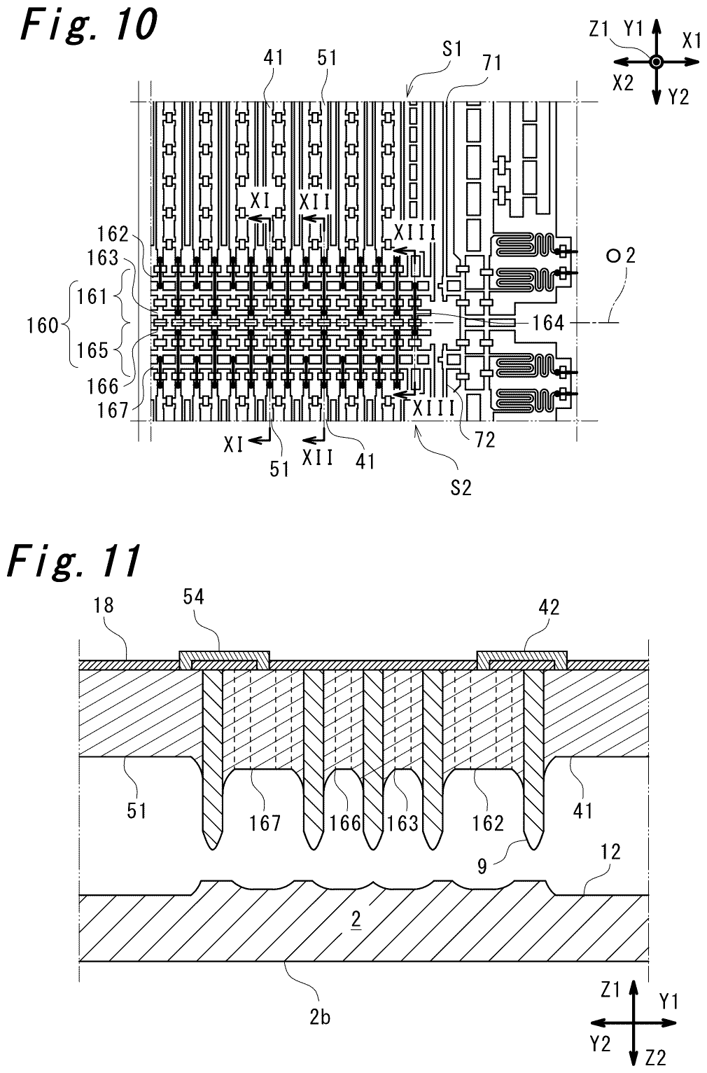

FIG. 10 is an enlarged diagram of the conductive path portion 160 around the X1 side. As illustrated in FIG. 10, since the anchor 91 and the anchor connection frame 93 are not provided, a first conductive path portion 161 and a second conductive path portion 165 are directly connected in the Y direction via the isolation joint 9, and the ninth and tenth flexible leads 89a and 89b are not provided. The conductive path portion 160 constitutes an I-shaped proof mass extending in the X direction in six rows.

FIG. 11 is a cross-sectional view taken along the first movable electrode element 41 in the first region S1 (the second movable electrode element 51 in the second region S2) along line XI-XI in FIG. 10. As illustrated in FIG. 11, in the first region S1, the first movable electrode element 41 is electrically connected to a first conductive path first portion 162 via the first wiring layer 42, and in the second region S2, the second movable electrode element 51 is electrically connected to a second conductive path second portion 167 via the fourth wiring layer 54.

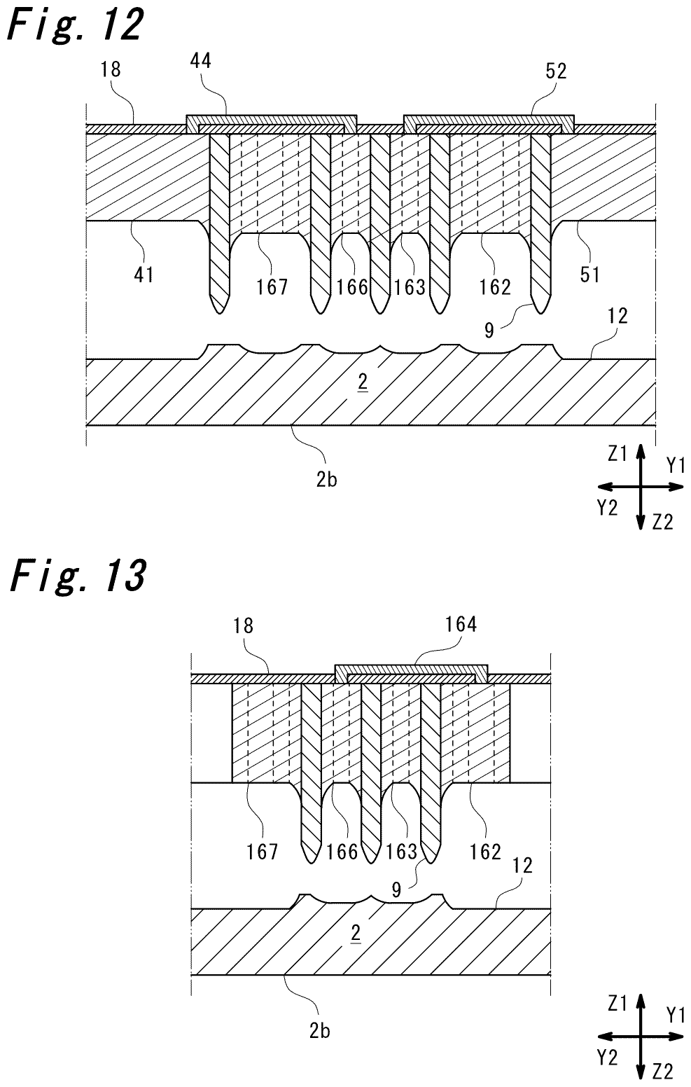

FIG. 12 is a cross-sectional view taken along the second movable electrode element 51 in the first region S1 (the first movable electrode element 41 in the second region S2) along line XII-XII in FIG. 10. As illustrated in FIG. 12, in the first region S1, the second movable electrode element 51 is electrically connected to a first conductive path second portion 163 via the second wiring layer 52, and in the second region S2, the first movable electrode element 41 is electrically connected to a second conductive path first portion 166 via the third wiring layer 44.

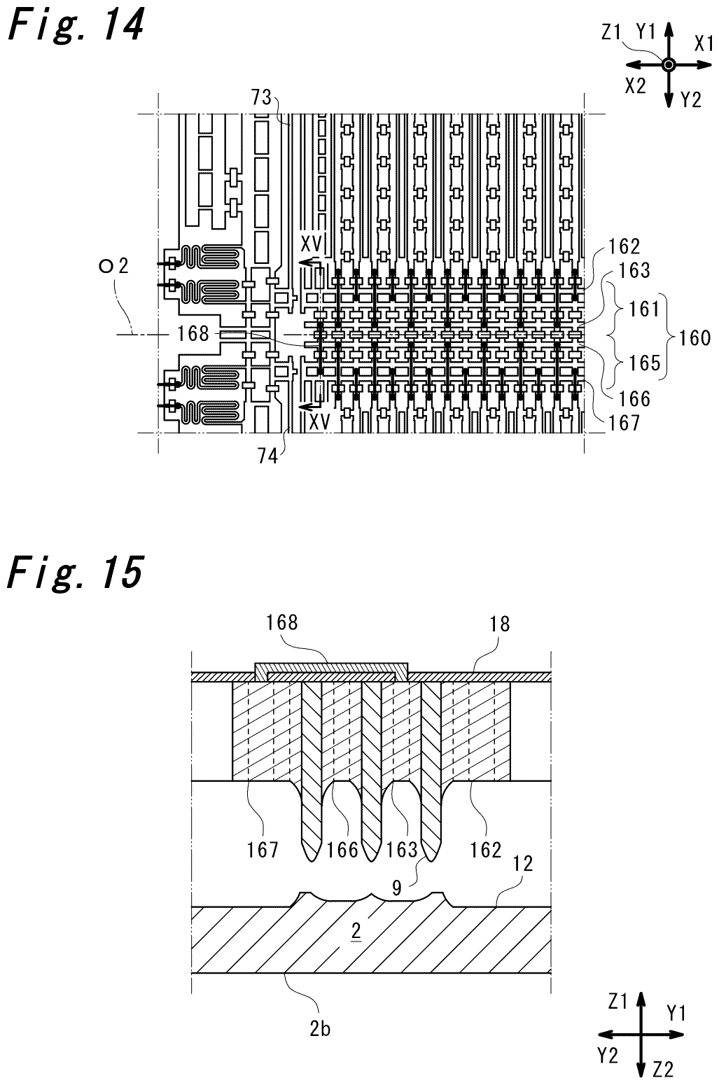

FIG. 14 is an enlarged view of the conductive path portion 160 around the X2 side. As illustrated in FIGS. 10 and 14, the conductive path portion 160 includes a seventh wiring layer 164 that electrically connects the first conductive path first portion 162 and the second conductive path first portion 166, and an eighth wiring layer 168 that electrically connects the first conductive path second portion 163 and the second conductive path second portion 167. The seventh wiring layer 164 is provided at an end portion on the X1 side of the conductive path portion 160, specifically, at a position corresponding to the first and second fixed electrode extension portions 23 and 33 in the X direction. The eighth wiring layer 168 is provided at an end portion on the X2 side of the conductive path portion 160, specifically, at a position corresponding to the first and second fixed electrode extension portions 23 and 33 in the X direction.

FIG. 13 is a cross-sectional view taken along the seventh wiring layer 164 along line XIII-XIII in FIG. 10. As illustrated in FIG. 13, the seventh wiring layer 164 is formed on the insulating film 18 laminated on a surface on the Z1 side of the conductive path portion 160, and electrically connects the first conductive path first portion 162 and the second conductive path first portion 166 via a contact penetrating insulating film 18 in the Z direction.

FIG. 15 is a cross-sectional view taken along the eighth wiring layer 168 along line XV-XV in FIG. 14. As illustrated in FIG. 15, the eighth wiring layer 168 is formed on the insulating film 18 laminated on a surface on the Z1 side of the conductive path portion 160, and electrically connects the first conductive path second portion 163 and the second conductive path second portion 167 via a contact penetrating insulating film 18 in the Z direction.

Also in the present embodiment, while being connected to a single proof mass constituted by the conductive path portion 160 via the isolation joint 9, the first movable electrode element 41 and the second movable electrode element 51 are electrically connected to the corresponding conductive path portion 160 while maintaining insulation via the first wiring layer 42, the second wiring layer 52, the third wiring layer 44, and the fourth wiring layer 54. Therefore, a fully differential acceleration sensor can be configured by the sensor unit 103, and output in which both common mode noise and the like and individual noise are canceled can be obtained as in the first embodiment, so that calculation accuracy of acceleration can be improved based on the output.

### Third Embodiment (Reference)

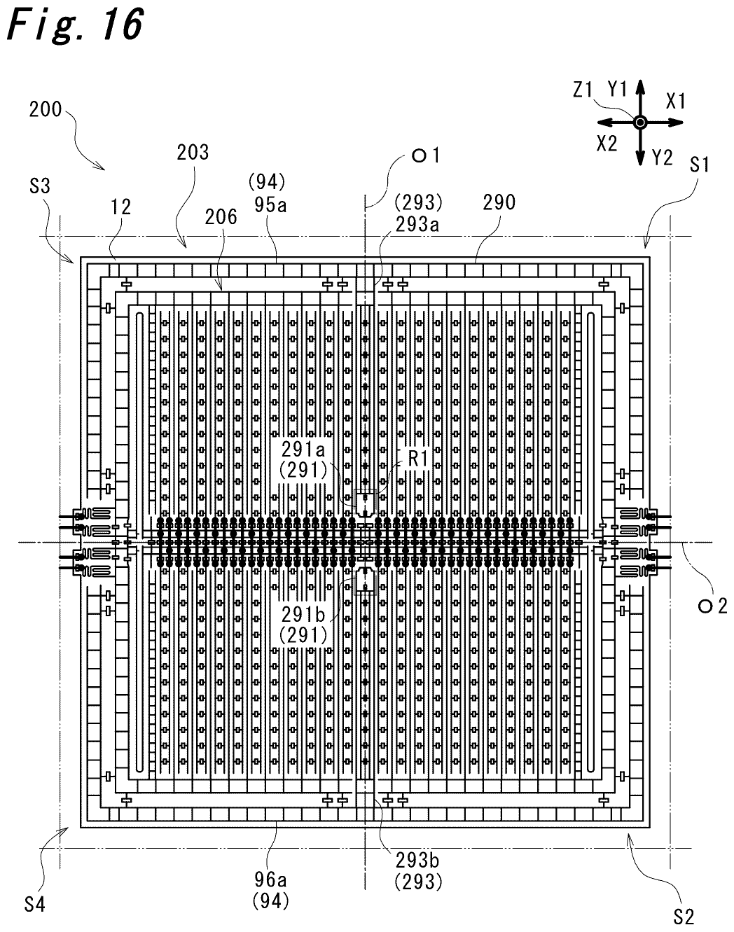

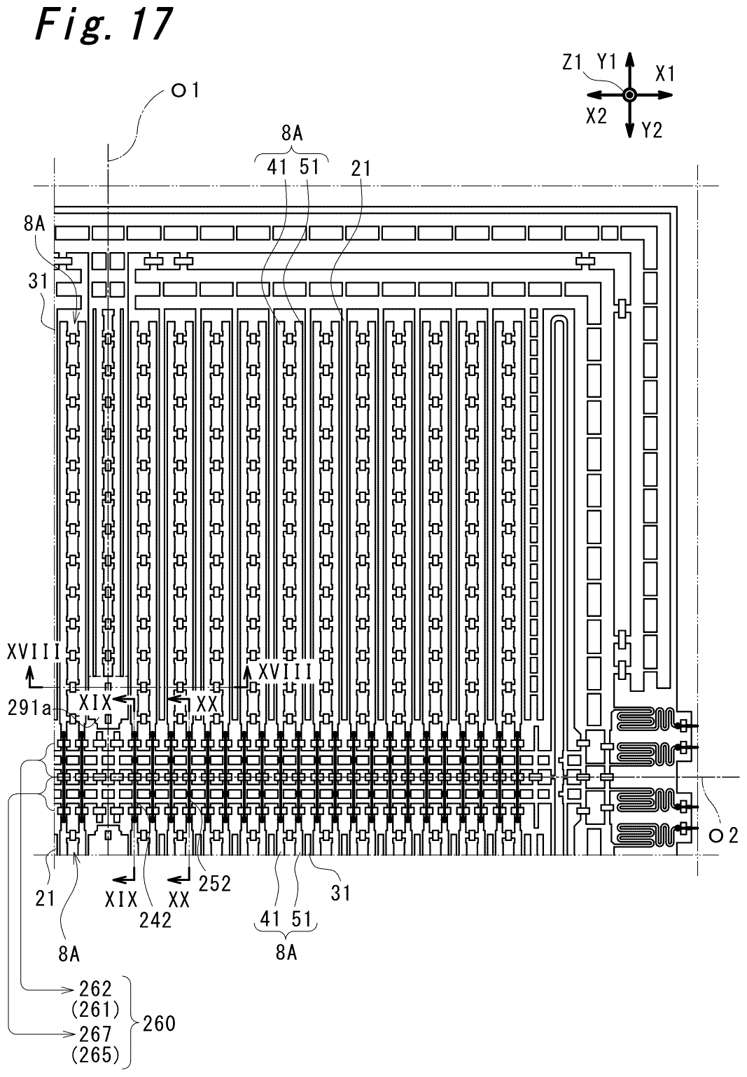

FIG. 16 is an enlarged plan view similar to FIG. 2 illustrating a sensor unit 203 of an acceleration sensor 200 according to a third embodiment of the present disclosure. As illustrated in FIG. 16, the sensor unit 203 is different from the sensor unit 3 of the first embodiment in a configuration of a conductive path portion 260 (see FIG. 17) and a frame 290. Furthermore, the sensor unit 203 is also different from the sensor unit 3 in that the first and second capacitors C1 and C2 are commonly provided in each of the first to fourth regions S1 to S4, and the third and fourth capacitors C3 and C4 are not provided. Components common to the sensor unit 3 are denoted by the same reference numerals, and will be omitted from description.

First, a configuration of the frame 290 will be described. The frame 290 is different from the frame 90 according to the first embodiment in a configuration of an anchor 291 and an anchor connection frame 293. Specifically, the anchors 291 are provided in a pair in the Y direction across the conductive path portion 260 in an anchor region R1 long in the Y direction located at the center of the recessed portion bottom surface 12, and include a first anchor 291a located on the Y1 side and a second anchor 291b located on the Y2 side.

The anchor connection frame 293 includes a first connection frame 293a connected to the first anchor 291a and a second connection frame 293b connected to the second anchor 291b. The first connection frame 293a extends from the first anchor 291a toward the Y1 side and is connected to an X-direction central portion of the first frame first portion 95a. The second connection frame 293b extends from the second anchor 291b toward the Y2 side and is connected to the second frame first portion 96a.

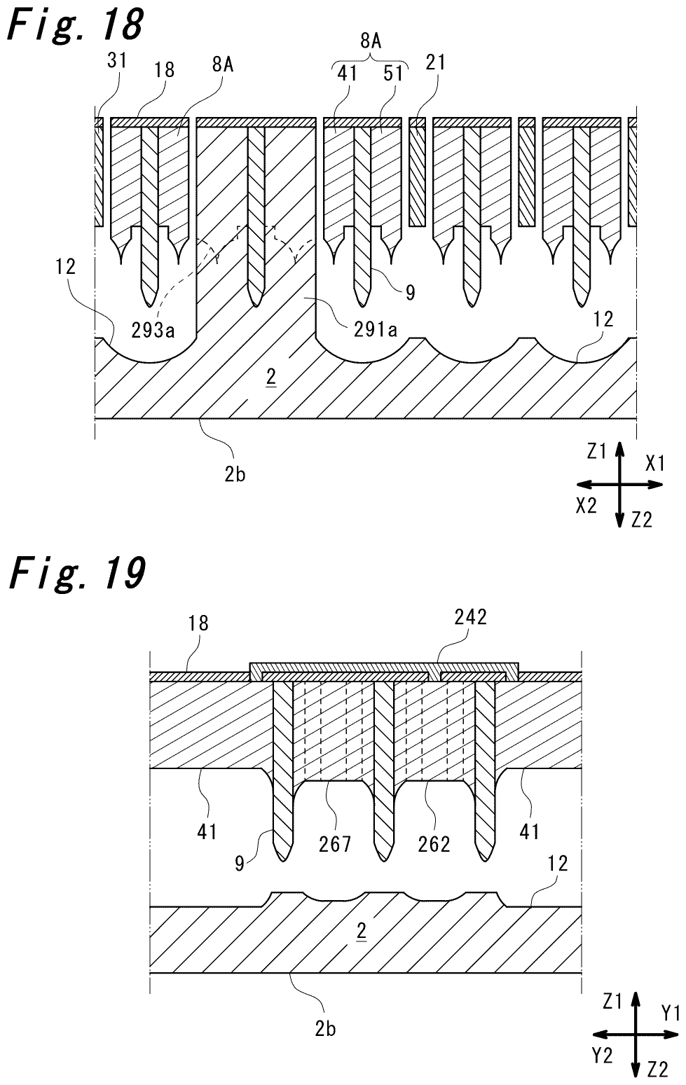

In the frame 290, the anchor 291, the anchor connection frame 293, and the base frame 94 are integrally formed by processing the device-side substrate 2 made from conductive silicon with a MEMS technique. FIG. 17 is an enlarged plan view illustrating a periphery of the first region S1 of the sensor unit 203. FIG. 18 is a cross-sectional view parallel to the X direction passing through the first anchor 291a taken along line XVIII-XVIII in FIG. 17. As illustrated in FIG. 18, the first anchor 291a projects from the recessed portion bottom surface 12 toward the Z1 side, whereas the first connecting frame 293a is separated from the recessed portion bottom surface 12 toward the Z1 side.

Next, a configuration of a MEMS electrode 206 will be described with reference to FIGS. 16 and 17. In the present embodiment, arrangement of the first and second movable electrode elements 41 and 51 is common in all of the first to fourth regions S1 to S4, and the first and second fixed electrode elements 21 and 31 are the same as those in the first and second embodiments. Specifically, in all of the first to fourth regions S1 to S4, the first set movable electrode element 8A is constituted by the first movable electrode element 41 and the second movable electrode element 51 located adjacent to the X1 side of the first movable electrode element 41.

That is, in the first and fourth regions S1 and S4, the first set movable electrode element 8A and the first fixed electrode element 21 are alternately arranged to face each other in the X direction. In the first and fourth regions S1 and S4, the first fixed electrode element 21 and the first movable electrode element 41 located on the X1 side of the first fixed electrode element 21 constitute the first capacitor C1, and the first fixed electrode element 21 and the second movable electrode element 51 located on the X2 side of the first fixed electrode element 21 constitute the second capacitor C2.

On the other hand, in the second and third regions S2 and S3, the first set movable electrode element 8A and the second fixed electrode element 31 are alternately arranged to face each other in the X direction. In the second and third regions S2 and S3, the second fixed electrode element 31 and the first movable electrode element 41 located on the X1 side of the second fixed electrode element 31 constitute the third capacitor C3, and the second fixed electrode element 31 and the second movable electrode element 51 located on the X2 side of the second fixed electrode element 31 constitute the fourth capacitor C4.

The conductive path portion 260 includes a first conductive path portion 261 located on the Y1 side and a second conductive path portion 265 located on the Y2 side. In the first conductive path portion 261, Y2-side end portions of the first set movable electrode element 8A located in the first and third regions S1 and S3 are connected via the isolation joint 9. In the second conductive path portion 265, Y1-side end portions of the first set movable electrode element 8A located in the second and fourth regions S2 and S4 are connected via the isolation joint 9.

Each of the first and second conductive path portions 261 and 265 is configured in a ladder shape such that a portion extending in the X direction in two rows and a portion extending in the Y direction from each of the first and second movable electrode elements 41 and 51 intersect each other. In the first conductive path portion 261, only a first conductive path first portion 262 is configured. In the second conductive path portion 265, only a second conductive path second portion 267 is configured.

FIG. 19 is a cross-sectional view taken along the first movable electrode element 41 along line XIX-XIX of FIG. 17. As illustrated in FIG. 19, all of the first movable electrode elements 41 located on the Y1 side and the Y2 side with respect to the conductive path portion 260 are electrically connected to the first conductive path first portion 262 via a first wiring layer 242.

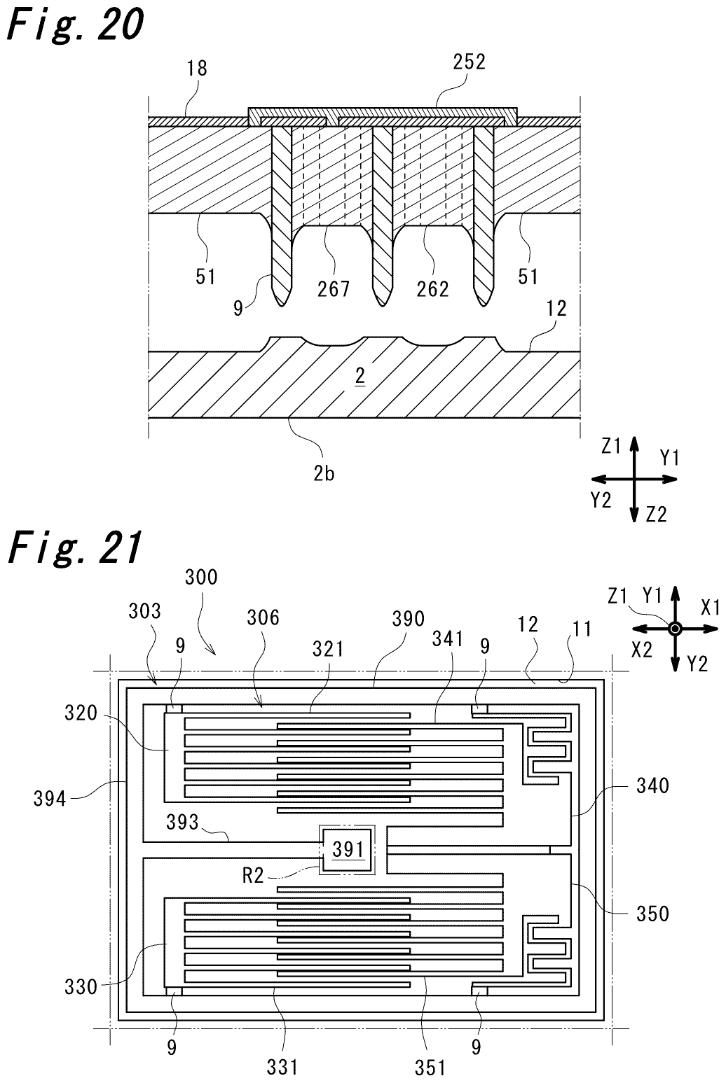

FIG. 20 is a cross-sectional view taken along the second movable electrode element 51 along line XX-XX in FIG. 17. As illustrated in FIG. 20, all of the second movable electrode elements 51 located on the Y1 side and the Y2 side with respect to the conductive path portion 260 are electrically connected to the second conductive path second portion 267 via a second wiring layer 252.

Both the first and second wiring layers 242 and 252 are formed on the insulating film 18 laminated on a Z1-side surface of the conductive path portion 260, and are electrically connected to the first and second movable electrode elements 41 and 51, the first conductive path portion 261, and the second conductive path portion 265 via a contact penetrating the insulating film 18. The first and second wiring layers 242 and 252 are made from conductive metal, for example, aluminum.

Also according to the present embodiment, since the MEMS electrode 6 includes the conductive path portion 260 configured as one proof mass, individual noise caused by individual variation may be commonly included in output voltage output based on a change in capacitance of the first to fourth capacitors C1 to C4. Further, since the MEMS electrode 206 is supported by the anchor region R1 of the recessed portion bottom surface 12 via the frame 290, package stress is hardly transmitted to the MEMS electrodes 206.

### Fourth Embodiment (Reference)

FIG. 21 is an enlarged plan view similar to FIG. 2 illustrating a sensor unit 303 of an acceleration sensor 300 according to a fourth embodiment of the present disclosure. As illustrated in FIG. 21, in the sensor unit 303, a MEMS electrode 306 is supported by an anchor region R2 located at the center of the recessed portion bottom surface 12 via a frame 390.

The frame 390 includes an anchor 391 located in the anchor region R2, an anchor connection frame 393 extending from the anchor 391 to the X2 side, and a base frame 394 extending along the recessed portion wall surface 11 and connected to the anchor connection frame 393. The frame 390 is different from the frame 90 according to the first embodiment and the frame 290 according to the third embodiment in that the anchor connection frame 393 is not formed in a pair but is formed of only one. In the frame 390, the anchor connection frame 393 and the base frame 394 are separated from the recessed portion bottom surface 12 toward the Z1 side, and are not connected to any of the other recessed portion wall surfaces 11.

The MEMS electrode 306 includes a first fixed electrode 320 and a first movable electrode 340 which are located on the Y1 side, and a second fixed electrode 330 and a second movable electrode 350 which are located on the Y2 side. A plurality of first fixed electrode elements 321 of the first fixed electrode 320 and a plurality of first movable electrode elements 341 of the first movable electrode 340 are arranged to face each other in the Y direction. Similarly, a plurality of second fixed electrode elements 331 of the second fixed electrode 330 and a plurality of second movable electrode elements 351 of the second movable electrode 350 are arranged to face each other in the Y direction.

The first and second fixed electrodes 320 and 330 and the first and second movable electrodes 340 and 350 are connected to the base frame 394 via the isolation joint 9. Also in the present embodiment, since the MEMS electrode 306 is supported by the anchor region R2 of the recessed portion bottom surface 12 via the frame 390, package stress is hardly transmitted to the MEMS electrodes 306.

### Fifth Embodiment (Reference)

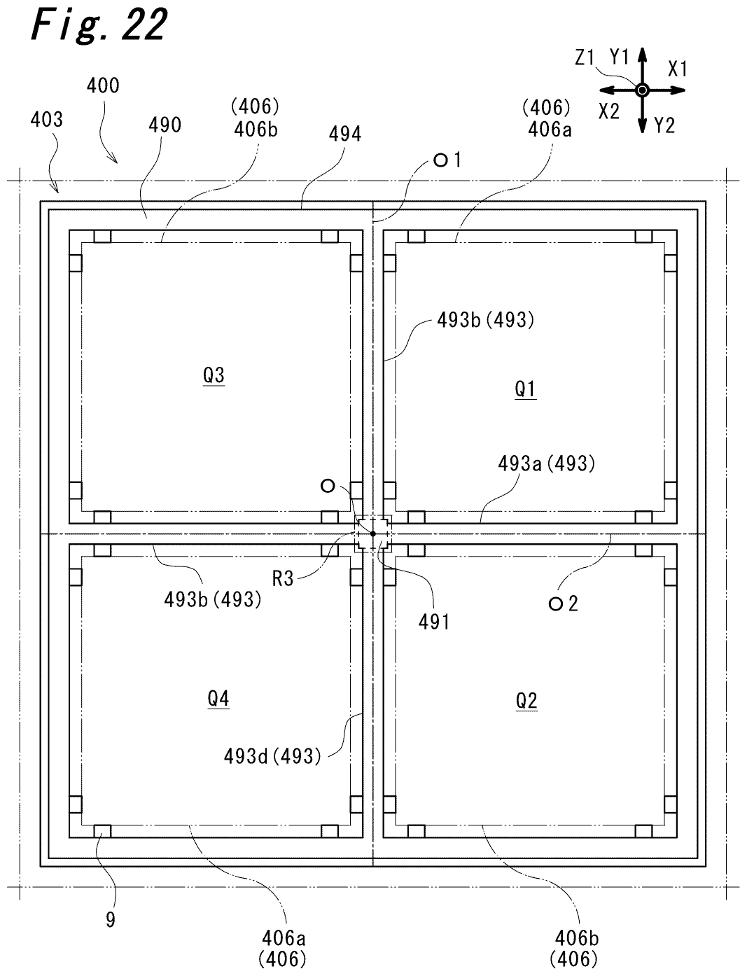

FIG. 22 is an enlarged plan view similar to FIG. 2 illustrating a sensor unit 403 of an acceleration sensor 400 according to a fifth embodiment of the present disclosure. As illustrated in FIG. 22, in the sensor unit 403, four MEMS electrodes 406 are supported by an anchor region R3 located at the center of the recessed portion bottom surface 12 via a frame 490.

The frame 490 includes an anchor 491 located in the anchor region R3, an anchor connection frame 493 extending from the anchor 491 to both sides in the X direction and both sides in the Y direction, and a base frame 494 extending along the recessed portion wall surface 11 and connected to the anchor connection frame 493. The frame 490 is different from the frame 90 of the first embodiment and the frame 290 of the third embodiment in that the anchor connection frames 493 are configured as a pair in both the X direction and the Y direction. In the frame 490, the anchor connection frame 493 and the base frame 494 are separated from the recessed portion bottom surface 12 toward the Z1 side, and are not connected to any of the other recessed portion wall surfaces 11.

The anchor connection frame 493 includes a first connection frame 493a extending from the anchor 491 to the X1 side, a second connection frame 493b extending from the anchor 491 to the X2 side, a third connection frame 493c extending from the anchor 491 to the Y1 side, and a fourth connection frame 493d extending from the anchor 491 to the Y2 side. Each of the first to fourth connection frames 493a to 493d is connected to each side of the base frame 494. Therefore, in the frame 490, first to fourth closed spaces Q1 to Q4 having a rectangular shape in plan view are formed in the first region S1, the second region S2, the third region S3, and the fourth region S4 respectively.

A MEMS electrode 406a for detecting acceleration in the Y direction is arranged in the first and fourth closed spaces Q1 and Q4 located diagonally across the center O, and a MEMS electrode 406b for detecting acceleration in the X direction is arranged in the second and third closed spaces Q2 and Q3. Each of the MEMS electrodes 406 is connected to the anchor connection frame 493 and/or the base frame 494 via the isolation joint 9.

According to the present embodiment, since four of the MEMS electrodes 406 are supported by the anchor region R3 of the recessed portion bottom surface 12 via one of the frame 490, package stress is hardly transmitted to the MEMS electrodes 406.

Note that the present disclosure is not limited to the configuration described in the above embodiment, and various modifications are possible.

### Supplementary Note

An acceleration sensor according to the present disclosure provides an aspect below.

### [Aspect 1]

An acceleration sensor including:
a substrate having a first main surface and a second main surface facing the first main surface;
a recessed portion recessed from the first main surface toward the second main surface;
a MEMS electrode that is provided in the recessed portion, includes a fixed electrode having a first fixed electrode and a second fixed electrode electrically insulated from the first fixed electrode, and a movable electrode having a first movable electrode and a second movable electrode electrically insulated from the first movable electrode, and constitutes a differential circuit; and
an isolation joint that mechanically connects the first movable electrode and the second movable electrode while electrically insulating the first movable electrode and the second movable electrode.

### [Aspect 2]

The acceleration sensor according to aspect 1, in which
the first fixed electrode includes a plurality of first fixed electrode elements,
the second fixed electrode includes a plurality of second fixed electrode elements,
the first movable electrode includes a plurality of first movable electrode elements,
the second movable electrode includes a plurality of second movable electrode elements,
the MEMS electrode includes:
a first capacitor including the plurality of first fixed electrode elements and the plurality of first movable electrode elements facing each of the plurality of first fixed electrode elements in a first direction;
a second capacitor including the plurality of first fixed electrode elements and the plurality of second movable electrode elements facing each of the plurality of first fixed electrode elements in the first direction;
a third capacitor including the plurality of second fixed electrode elements and the plurality of first movable electrode elements facing each of the plurality of second fixed electrode elements in the first direction; and
a fourth capacitor including the plurality of second fixed electrode elements and the plurality of second movable electrode elements facing each of the plurality of second fixed electrode elements in the first direction, and
when the first movable electrode and the second movable electrode are displaced in the first direction in a state where input voltages of opposite phases are input to the first movable electrode and the second movable electrode, output voltages of opposite phases are output from the first fixed electrode and the second fixed electrode.

### [Aspect 3]

The acceleration sensor according to aspect 2, in which
the MEMS electrode includes, in plan view:
the first capacitor and the second capacitor in a first region located on one side in a second direction orthogonal to the first direction; and
the third capacitor and the fourth capacitor in a second region located on the other side in the second direction,
in the first region, the first movable electrode element and the second movable electrode element arranged adjacent to one side in the first direction of the first movable electrode element are connected to each other via the isolation joint, these constitute a first set movable electrode element, and each of a plurality of the first set movable electrode elements and each of the plurality of first fixed electrode elements are alternately arranged in the first direction, and
in the second region, the first movable electrode element and the second movable electrode element arranged adjacent to the other side in the first direction of the first movable electrode element are connected to each other via the isolation joint, these constitute a second set movable electrode element, and each of a plurality of the second set movable electrode elements and each of the plurality of second fixed electrode elements are alternately arranged in the first direction.

### [Aspect 4]

The acceleration sensor according to aspect 3, in which the movable electrode further includes a conductive path portion extending in the first direction between the plurality of first set movable electrode elements and the plurality of second set movable electrode elements.

### [Aspect 5]

The acceleration sensor according to aspect 4, in which
the conductive path portion includes:
a first conductive path portion mechanically connected to the plurality of first set movable electrode elements; and
a second conductive path portion mechanically connected to the plurality of second set movable electrode elements.

### [Aspect 6]

The acceleration sensor according to aspect 5, in which
the first conductive path portion includes a first conductive path first portion electrically connected to the first movable electrode element and a first conductive path second portion electrically connected to the second movable electrode element,
the second conductive path portion includes a second conductive path first portion electrically connected to the first movable electrode element, and a second conductive path second portion electrically connected to the second movable electrode element,
the first conductive path first portion and the second conductive path first portion are electrically connected, and
the first conductive path second portion and the second conductive path second portion are electrically connected.

### [Aspect 7]

The acceleration sensor according to aspect 6, in which
the first conductive path first portion and the first conductive path second portion are connected via the isolation joint, and
the second conductive path first portion and the second conductive path second portion are connected via the isolation joint.

### [Aspect 8]

The acceleration sensor according to aspect 7, in which the first conductive path portion and the second conductive path portion are connected via the isolation joint.

### [Aspect 9]

The acceleration sensor according to aspect 8, in which
the first conductive path first portion and the second conductive path first portion are electrically connected via a first wiring layer, and
the first conductive path second portion and the second conductive path second portion are electrically connected via a second wiring layer different from the first wiring layer.

### [Aspect 10]

The acceleration sensor according to any one of aspects 6 to 9, in which each of the first conductive path portion and the second conductive path portion includes a spring portion that elastically deforms in the first direction at both end portions in the first direction.

### [Aspect 11]

The acceleration sensor according to any one of aspects 3 to 10, further including, in the recessed portion, in plan view:
a third region adjacent to the first region in the first direction; and
a fourth region adjacent to the second region in the first direction and adjacent to the third region in the second direction, in which
the first capacitor and the second capacitor are also located in the fourth region in addition to the first region, and
the second capacitor and the third capacitor are located in the third region in addition to the second region.

### [Aspect 12]

An acceleration sensor including:
a substrate having a first main surface and a second main surface facing the first main surface;
a recessed portion recessed from the first main surface toward the second main surface and defined by a plurality of recessed portion wall surfaces;
an anchor projecting from an anchor region that is a partial region of a first wall surface included in a plurality of the recessed portion wall surfaces;
a suspension frame having one end portion connected to the anchor and extending in the recessed portion, the suspension frame being separated from a plurality of the recessed portion wall surfaces;
a MEMS electrode located in the recessed portion; and
an isolation joint that mechanically connects the MEMS electrode to the suspension frame while electrically insulating the MEMS electrode from the suspension frame.

### [Aspect 13]

The acceleration sensor according to aspect 12, in which
the anchor region is located in a recessed portion bottom surface which is a bottom surface of the recessed portion.

### [Aspect 14]

The acceleration sensor according to aspect 13, in which
the anchor region has a width dimension of 2.5 μm or more and 25 μm or less.

### [Aspect 15]

The acceleration sensor according to aspect 14, in which
the anchor region includes the center in plan view of the recessed portion bottom surface.

### [Aspect 16]

The acceleration sensor according to aspect 15, in which
the anchor has a center in plan view, which coincides with the center of the recessed portion bottom surface.

### [Aspect 17]

The acceleration sensor of any one of aspects 12 to 16, in which
the suspension frame includes:
an anchor connection frame extending from the anchor toward the recessed portion wall surface; and
a base frame rigidly connected directly or indirectly to the anchor connection frame, the base frame extending along a plurality of the recessed portion wall surfaces around the MEMS electrode.

### [Aspect 18]

The acceleration sensor according to aspect 17, in which
the MEMS electrode is supported by the base frame.

### [Aspect 19]

The acceleration sensor according to any one of aspects 12 to 18, in which
the MEMS electrode includes:
a fixed electrode including a plurality of fixed electrode elements; and
a movable electrode including a plurality of movable electrode elements facing a plurality of the fixed electrode elements,

### [Aspect 20]

The acceleration sensor according to aspect 19, in which
the anchor includes:
a first anchor; and
a second anchor separated from the first anchor.

### [Aspect 21]

The acceleration sensor according to aspect 20, in which
the movable electrode further includes a conductive path portion connected to a plurality of the movable electrode elements, and
the conductive path portion extends in a second direction intersecting a first direction in which the first anchor and the second anchor are aligned between the first anchor and the second anchor.

### [Aspect 22]

The acceleration sensor according to aspect 21, in which
the fixed electrode and the movable electrode are connected to the recessed portion wall surface via a flexible lead that is conductive and is elastically deformable.

### EXPLANATION OF REFERENCES

1 acceleration sensor
2 device-side substrate
3 sensor unit
4 electrode pad
6 MEMS electrode
7 fixed electrode
8 movable electrode
8A first set movable electrode element
8B second set movable electrode element
9 isolation joint
10 recessed portion
11 recessed portion wall surface
12 recessed portion bottom surface
18 insulating film
20 first fixed electrode
21 first fixed electrode element
22 first fixed electrode base portion
23 first fixed electrode extension portion
30 second fixed electrode
31 second fixed electrode element
32 second fixed electrode base portion
33 second fixed electrode extension portion
40 first movable electrode
41 first movable electrode element
42 first wiring layer
44 third wiring layer
50 second movable electrode
51 second movable electrode element
52 second wiring layer
54 fourth wiring layer
60 conductive path portion
61 first conductive path portion
62 first conductive path first portion
63 first conductive path second portion
64 connection portion first wiring layer
65 second conductive path portion
66 second conductive path first portion
67 second conductive path second portion
68 connection portion second wiring layer
69 conductive path connection portion
71 first spring portion
72 second spring portion
73 third spring portion
74 fourth spring portion
76 first conductive path base portion
78 second conductive path base portion
81 first flexible lead
82 second flexible lead
83 third flexible lead
84 fourth flexible lead
85 fifth flexible lead
86 sixth flexible lead
87 seventh flexible lead
88 eighth flexible lead
89a ninth flexible lead
89b tenth flexible lead
90 frame
91 anchor
91a first anchor
91b second anchor
92 suspension frame
93 anchor connection frame
93a first connection frame
93b second connection frame
94 base frame
95 first base frame
96 second base frame

What is claimed is:

1. An acceleration sensor comprising:
a substrate having a first main surface and a second main surface facing the first main surface;
a recessed portion recessed from the first main surface toward the second main surface;
a MEMS electrode that is provided in the recessed portion, includes a fixed electrode having a first fixed electrode and a second fixed electrode electrically insulated from the first fixed electrode, and a movable electrode having a first movable electrode and a second movable electrode electrically insulated from the first movable electrode, and constitutes a differential circuit; and
an isolation joint that mechanically connects the first movable electrode and the second movable electrode while electrically insulating the first movable electrode and the second movable electrode.

2. The acceleration sensor according to claim 1, wherein
the first fixed electrode includes a plurality of first fixed electrode elements,
the second fixed electrode includes a plurality of second fixed electrode elements,
the first movable electrode includes a plurality of first movable electrode elements,
the second movable electrode includes a plurality of second movable electrode elements,
the MEMS electrode includes:
a first capacitor including the plurality of first fixed electrode elements and the plurality of first movable electrode elements facing each of the plurality of first fixed electrode elements in a first direction;
a second capacitor including the plurality of first fixed electrode elements and the plurality of second movable electrode elements facing each of the plurality of first fixed electrode elements in the first direction;
a third capacitor including the plurality of second fixed electrode elements and the plurality of first movable electrode elements facing each of the plurality of second fixed electrode elements in the first direction; and
a fourth capacitor including the plurality of second fixed electrode elements and the plurality of second movable electrode elements facing each of the plurality of second fixed electrode elements in the first direction, and
when the first movable electrode and the second movable electrode are displaced in the first direction in a state where input voltages of opposite phases are input to the first movable electrode and the second movable electrode, output voltages of opposite phases are output from the first fixed electrode and the second fixed electrode.

3. The acceleration sensor according to claim 2, wherein
the MEMS electrode includes, in plan view:
the first capacitor and the second capacitor in a first region located on one side in a second direction orthogonal to the first direction; and
the third capacitor and the fourth capacitor in a second region located on the other side in the second direction,
in the first region, the first movable electrode element and the second movable electrode element arranged adjacent to one side in the first direction of the first movable electrode element are connected to each other via the isolation joint, these constitute a first set movable electrode element, and each of a plurality of the first set movable electrode elements and each of the plurality of first fixed electrode elements are alternately arranged in the first direction, and
in the second region, the first movable electrode element and the second movable electrode element arranged adjacent to the other side in the first direction of the first movable electrode element are connected to each other via the isolation joint, these constitute a second set movable electrode element, and each of a plurality of the second set movable electrode elements and each of the plurality of second fixed electrode elements are alternately arranged in the first direction.

4. The acceleration sensor according to claim 3, wherein the movable electrode further includes a conductive path portion extending in the first direction between the plurality of first set movable electrode elements and the plurality of second set movable electrode elements.

5. The acceleration sensor according to claim 4, wherein
the conductive path portion includes:
a first conductive path portion mechanically connected to the plurality of first set movable electrode elements; and
a second conductive path portion mechanically connected to the plurality of second set movable electrode elements.

6. The acceleration sensor according to claim 5, wherein
the first conductive path portion includes a first conductive path first portion electrically connected to the first movable electrode element and a first conductive path second portion electrically connected to the second movable electrode element,
the second conductive path portion includes a second conductive path first portion electrically connected to the first movable electrode element, and a second conductive path second portion electrically connected to the second movable electrode element,
the first conductive path first portion and the second conductive path first portion are electrically connected, and
the first conductive path second portion and the second conductive path second portion are electrically connected.

7. The acceleration sensor according to claim 6, wherein
the first conductive path first portion and the first conductive path second portion are connected via the isolation joint, and
the second conductive path first portion and the second conductive path second portion are connected via the isolation joint.

8. The acceleration sensor according to claim 7, wherein the first conductive path portion and the second conductive path portion are connected via the isolation joint.

9. The acceleration sensor according to claim 8, wherein
the first conductive path first portion and the second conductive path first portion are electrically connected via a first wiring layer, and
the first conductive path second portion and the second conductive path second portion are electrically connected via a second wiring layer different from the first wiring layer.

10. The acceleration sensor according to any one of claim 6, wherein each of the first conductive path portion and the second conductive path portion includes a spring portion that elastically deforms in the first direction at both end portions in the first direction.

11. The acceleration sensor according to any one of claim 3, further comprising, in the recessed portion, in plan view:
a third region adjacent to the first region in the first direction; and
a fourth region adjacent to the second region in the first direction and adjacent to the third region in the second direction, wherein
the first capacitor and the second capacitor are also located in the fourth region in addition to the first region, and
the second capacitor and the third capacitor are located in the third region in addition to the second region.
